(19) United States
(12) Patent Application Publication
(10) Pub. No.: US 2026/0018481 A1
(43) Pub. Date: Jan. 15, 2026

(54) ELECTRONIC DEVICE

(71) Applicant: SONY SEMICONDUCTOR SOLUTIONS CORPORATION, KANAGAWA (JP)

(72) Inventors: KAZUKI SHIMOMURA, KANAGAWA (JP); NOBUTOSHI FUJII, KANAGAWA (JP); YUICHI YAMAMOTO, KANAGAWA (JP); YUTA NAKAMURA, KANAGAWA (JP); TOKIHISA KANEGUCHI, KANAGAWA (JP)

(21) Appl. No.: 18/880,854

(22) PCT Filed: Jul. 25, 2023
(86) PCT No.: PCT/JP2023/027235

§ 371 Date: Jan. 3, 2025

(30) Foreign Application Priority Data
Jul. 26, 2022 (JP) 2022-119066

(51) Int. Cl. H01L 23/367; H10F 39/00

(52) U.S. Cl. CPC H01L 23/367; H10F 39/809

(57) ABSTRACT

Provided is an electronic device having further excellent operation reliability. An electronic device according to an embodiment of the present disclosure includes a first device board, a second device board, and a hollow. The second device board is stacked on the first device board and electrically coupled to the first device board, and has an area larger than an area of the first device board. The hollow surrounds, along a plane orthogonal to a stacking direction of the first device board and the second device board, at least a portion of a periphery of the first device board.

### TECHNICAL FIELD

The present disclosure relates to an electronic device having a stacked structure in which two or more boards are stacked on each other.

### BACKGROUND ART

To achieve size reduction of an imaging device, there has been proposed a WoW (Wafer on Wafer) stacking technique that bonds: a wafer including an imaging element that generates a pixel signal; and a wafer including a signal processing circuit that performs a signal process on the pixel signal generated by the imaging element, a memory circuit, etc., to each other (for example, PTL 1).

### CITATION LIST

### Patent Literature

PTL 1: Japanese Unexamined Patent Application Publication No. 2014-099582

### SUMMARY OF THE INVENTION

Incidentally, it is desirable to improve operation reliability of an electronic device having such a stacked structure.

Accordingly, it is desirable to provide an electronic device having further excellent operation reliability.

An electronic device according to one embodiment of the present disclosure includes a first device board, a second device board, and a hollow. The second device board is stacked on the first device board and electrically coupled to the first device board, and has an area larger than an area of the first device board. The hollow surrounds, along a plane orthogonal to a stacking direction of the first device board and the second device board, at least a portion of a periphery of the first device board.

The electronic device according to one embodiment of the present disclosure includes the hollow surrounding at least a portion of the periphery of the first device board, which efficiently releases heat of the first device board.

### BRIEF DESCRIPTION OF DRAWINGS

FIG. 1A is a cross-sectional diagram illustrating a configuration example of a solid-state imaging device according to a first embodiment of the present disclosure.

FIG. 1B is a plan diagram illustrating the configuration example of the solid-state imaging device illustrated in FIG. 1A.

FIG. 2A is a cross-sectional diagram illustrating one step of a method of manufacturing the solid-state imaging device illustrated in FIG. 1A.

FIG. 2B is a cross-sectional diagram illustrating one step subsequent to that in FIG. 2A.

FIG. 2C is a cross-sectional diagram illustrating one step subsequent to that in FIG. 2B.

FIG. 2D is a cross-sectional diagram illustrating one step subsequent to that in FIG. 2C.

FIG. 2E is a cross-sectional diagram illustrating one step subsequent to that in FIG. 2D.

FIG. 2F is a cross-sectional diagram illustrating one step subsequent to that in FIG. 2E.

FIG. 2G is a planar schematic diagram illustrating one step subsequent to that in FIG. 2F.

FIG. 3A is a cross-sectional diagram illustrating a configuration example of a solid-state imaging device according to a first modification example of the first embodiment of the present disclosure.

FIG. 3B is a plan diagram illustrating the configuration example of the solid-state imaging device illustrated in FIG. 3A.

FIG. 4A is a cross-sectional diagram illustrating a configuration example of a solid-state imaging device according to a second modification example of the first embodiment of the present disclosure.

FIG. 4B is a plan diagram illustrating the configuration example of the solid-state imaging device illustrated in FIG. 4A.

FIG. 5A is a cross-sectional diagram illustrating one step of a method of manufacturing the solid-state imaging device illustrated in FIG. 4A.

FIG. 5B is a cross-sectional diagram illustrating one step subsequent to that in FIG. 5A.

FIG. 5C is a cross-sectional diagram illustrating one step subsequent to that in FIG. 5B.

FIG. 5D is a cross-sectional diagram illustrating one step subsequent to that in FIG. 5C.

FIG. 6A is a cross-sectional diagram illustrating a configuration example of a solid-state imaging device according to a third modification example of the first embodiment of the present disclosure.

FIG. 6B is a plan diagram illustrating the configuration example of the solid-state imaging device illustrated in FIG. 6A.

FIG. 7A is a cross-sectional diagram illustrating one step of a method of manufacturing the solid-state imaging device illustrated in FIG. 6A.

FIG. 7B is a cross-sectional diagram illustrating one step subsequent to that in FIG. 7A.

FIG. 7C is a cross-sectional diagram illustrating one step subsequent to that in FIG. 7B.

FIG. 7D is a cross-sectional diagram illustrating one step subsequent to that in FIG. 7C.

FIG. 8 is a plan diagram illustrating a configuration example of a solid-state imaging device according to a fourth modification example of the first embodiment of the present disclosure.

FIG. 9A is a cross-sectional diagram illustrating a configuration example of a solid-state imaging device according to a second embodiment of the present disclosure.

FIG. 9B is a plan diagram illustrating the configuration example of the solid-state imaging device illustrated in FIG. 9A.

FIG. 10 is a cross-sectional diagram illustrating a configuration example of a solid-state imaging device according to a first modification example of the second embodiment of the present disclosure.

FIG. 11 is a cross-sectional diagram illustrating a configuration example of a solid-state imaging device according to a second modification example of the second embodiment of the present disclosure.

FIG. 12 is a cross-sectional diagram illustrating a configuration example of a solid-state imaging device according to a third modification example of the second embodiment of the present disclosure.

FIG. 13A is a cross-sectional diagram illustrating a configuration example of a solid-state imaging device according to a third embodiment of the present disclosure.

FIG. 13B is a plan diagram illustrating the configuration example of the solid-state imaging device illustrated in FIG. 13A.

FIG. 14 is an enlarged cross-sectional diagram illustrating in an enlarged manner a configuration example of a logic board of the solid-state imaging device illustrated in FIG. 13A.

FIG. 15A is a cross-sectional diagram illustrating a configuration example of a solid-state imaging device according to a first modification example of the third embodiment of the present disclosure.

FIG. 15B is a cross-sectional diagram illustrating a configuration example of a solid-state imaging device according to a second modification example of the third embodiment of the present disclosure.

FIG. 15C is a cross-sectional diagram illustrating a configuration example of a solid-state imaging device according to a third modification example of the third embodiment of the present disclosure.

FIG. 15D is a cross-sectional diagram illustrating a configuration example of a solid-state imaging device according to a fourth modification example of the third embodiment of the present disclosure.

FIG. 16 is a plan diagram illustrating a configuration example of a logic board of a solid-state imaging device according to a fifth modification example of the third embodiment of the present disclosure.

FIG. 17 is a plan diagram illustrating a configuration example of a logic board of a solid-state imaging device according to a sixth modification example of the third embodiment of the present disclosure.

FIG. 18 is a cross-sectional diagram illustrating a configuration example of a logic board of a solid-state imaging device according to a seventh modification example of the third embodiment of the present disclosure.

FIG. 19 is a cross-sectional diagram illustrating a configuration example of a solid-state imaging device according to a fourth embodiment of the present disclosure.

FIG. 20 is a cross-sectional diagram illustrating a configuration example of a solid-state imaging device according to a fifth embodiment of the present disclosure.

FIG. 21 is a schematic diagram illustrating an overall configuration example of an electronic apparatus according to a second embodiment of the present disclosure.

FIG. 22 is a block diagram depicting an example of schematic configuration of a vehicle control system.

FIG. 23 is a diagram of assistance in explaining an example of installation positions of an outside-vehicle information detecting section and an imaging section.

### MODES FOR CARRYING OUT THE INVENTION

In the following, some embodiments of the present disclosure are described in detail with reference to the drawings. It is to be noted that description is given in the following order.

### 1. First Embodiment (Example of First Solid-State Imaging Device)

### 2. Modification Examples of First Embodiment (Modification Examples of First Solid-State Imaging Device)

### 3. Second Embodiment (Example of Second Solid-State Imaging Device)

### 4. Modification Examples of Second Embodiment (Modification Examples of Second Solid-State Imaging Device)

### 5. Third Embodiment (Example of Third Solid-State Imaging Device)

### 6. Modification Examples of Third Embodiment (Modification Examples of Fourth Solid-State Imaging Device)

### 7. Fourth Embodiment (Example of Fourth Solid-State Imaging Device)

### 8. Fifth Embodiment (Example of Fifth Solid-State Imaging Device)

### 9. Sixth Embodiment (Example of Application to Electronic Apparatus)

### 10. Example of Practical Application to Mobile Body

### 11. Other Modification Examples

### 1. First Embodiment

### [Configuration of Solid-State Imaging Device 1]

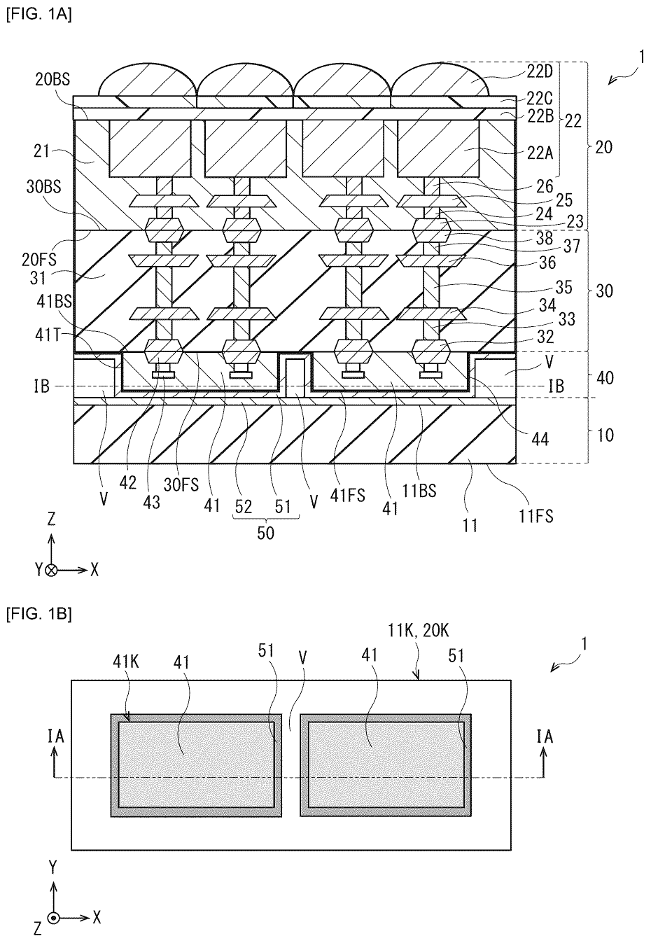

FIGS. 1A and 1B each schematically illustrate a configuration example of a solid-state imaging device 1 according to a first embodiment of the present disclosure. FIG. 1A illustrates a cross-sectional configuration example of the solid-state imaging device 1, and FIG. 1B illustrates a planar configuration example of the solid-state imaging device 1. FIG. 1A corresponds to a cross-sectional diagram of a stack in an arrow direction along a cutting line IA-IA illustrated in FIG. 1B. Further, FIG. 1A corresponds to a horizontal cross-sectional diagram at a height position indicated by a dashed line IB in FIG. 1A.

As illustrated in FIG. 1A, the solid-state imaging device 1 has a stacked structure in which a logic layer 40, an intermediate layer 30, and a sensor board 20 are stacked in this order on a support layer 10.

### [Support Layer 10]

The support layer 10 includes, for example, a support board 11 and a metal film 52. The support board 11 is, for example, a Si (silicon) board and has a front surface 11FS and a back surface 11BS. The metal film 52 is provided so as to cover the back surface 11BS.

### [Logic Layer 40]

The logic layer 40 includes one or more logic boards 41. FIGS. 1A and 1B each illustrate a case where two logic boards 41 are provided for one sensor board 20. However, the solid-state imaging device 1 may include only one logic board 41, or three of more logic boards 41. That is, the number of logic boards 41 for one sensor board 20 may be set as desired. The logic board 41 is electrically coupled to the sensor board 20 via the intermediate layer 30. The logic board 41 is a specific example corresponding to a “first device board” of the present disclosure. The sensor board 20 is a specific example corresponding to a “second device board” of the present disclosure.

As illustrated in FIGS. 1A and 1B, the two logic boards 41 are spaced apart from each other along an XY plane. The XY plane is orthogonal to a Z axis direction. The Z axis direction is a stacking direction of the logic board 41, the intermediate layer 30, and the sensor board 20. A hollow V is provided in a periphery of each logic board 41. The hollow V is provided so as to surround the periphery of the logic board 41 along the XY plane. The hollow V is, for example, a heatsink that releases heat generated in the logic board 41 to the periphery of the logic board 41. In the solid-state imaging device 1, the hollow V is provided at the same level as the logic board 41. It is to be noted that, in the solid-state imaging device 1, the hollow V is present so as to surround an outer edge 41K of the logic board 41 along the XY plane over the entire circumference. However, in the present disclosure, the hollow V may surround at least a portion of the logic board 41. The hollow V is also present in a space between a pair of adjacent logic boards 41. It is be noted that the hollow V may be provided in at least a portion of a space between the plurality of logic boards 41. That is, the present disclosure is not limited to a case where the hollow V is present in all of the space between the plurality of logic boards 41.

The hollow V may communicate with an outside of the solid-state imaging device 1. That is, outside air may be introduced into and discharged from the hollow V. In this case, the hollow V is available as a ventilation channel.

At least a portion of the hollow V is defined by a metal film 51 covering the logic board 41. That is, the hollow V is separated from the periphery thereof by the metal film 51. In the solid-state imaging device 1, the hollow V is defined by the metal film 51 and the metal film 52, and is separated from the logic board 41 and the support board 11. The metal film 51 continuously covers, for example, an end surface 41T of the logic board 41 along the outer edge 41K of logic board 41 and a front surface 41FS, of the logic board 41, on an opposite side of the sensor board 20. It is to be noted that the metal films 51 covering the plurality of adjacent logic boards 41 may be coupled with each other. In addition, an insulating layer 44 including, for example, SiN (silicon nitride) may be provided between: the metal film 51; and the end surface 41T and the front surface 41FS of the logic board 41. FIG. 1A illustrates an example of a case where the insulating layer 44 and the metal film 51 are formed so as to also cover a front surface 30FS of the intermediate layer 30 in the periphery of the logic board 41. Here, the metal film 51 and the metal film 52 are integrated with each other and configure one metal frame 50. Accordingly, it can be said that the hollow V is contained inside the metal frame 50. The metal film 51 and the metal film 52 may each include at least one of Al (aluminum), W (tungsten), or Cu (copper). The materials included in the metal film 51 and the materials included in the metal film 52 may be the same or different from each other. Further, the metal film 51 and the metal film 52 are each formable by, for example, an atomic layer deposition (ALD) method; however, a manufacturing method thereof is not limited thereto.

The logic board 41 is provided with a logic circuit. The logic circuit includes, for example, a wiring layer 42, and a semiconductor element 43 such as a transistor. A surface of a portion of the wiring layer 42 is exposed to a back surface 41BS of the logic board 41. The back surface 41BS of the logic board 41 is bonded to the front surface 30FS of the intermediate layer 30. The wiring layer 42 includes, for example, Cu (copper).

### [Intermediate Layer 30]

The intermediate layer 30 includes an insulating layer 31, and wiring layers 32 to 38 embedded in the insulating layer 31. The insulating layer 31 may include an inorganic oxide such as silicon oxide (SiOx) or silicon nitride (SiNx). The wiring layers 32 to 38 are sequentially stacked in the Z axis direction from the front surface 30FS to a back surface 30BS of the intermediate layer 30. The wiring layer 32 is exposed to the front surface 30FS and is bonded to the wiring layer 42 of the logic board 41. The wiring layers 32 to 38 each include, for example, Cu (copper). It is to be noted that the wiring layers 32 to 38 of FIG. 1A are each an example, and the number of wiring layers present in the intermediate layer 30, a size and a position of the wiring layer present in the intermediate layer 30, etc., are not limited to those illustrated in FIG. 1A. The back surface 30BS of the intermediate layer 30 is bonded to a front surface FS of the sensor board 20.

### [Sensor Board 20]

In the sensor board 20, a solid-state imaging element 22 and wiring layers 23 to 26 are provided in a base 21. An occupied area in the XY plane of the sensor board 20 is larger than an occupied area in the XY plane of the logic board 41. The solid-state imaging element 22 includes a plurality of pixels including, for example, photodiodes 22A, and is configured to generate a pixel signal by receiving external light on a pixel-by-pixel basis. The solid-state imaging element 22 further includes, for example, a protective film 22B, a color filter 22C, and a microlens 22D. The wiring layers 23 to 26 are sequentially stacked in the Z axis direction from the front surface 20FS to the photodiode 22A. The wiring layer 23 is exposed to the front surface 23FS and is bonded to the wiring layer 38 of the intermediate layer 30. The wiring layers 23 to 26 each include, for example, by Cu (copper). It is to be noted that the wiring layers 23 to 26 of FIG. 1A are each an example, and the number of wiring layers present in the sensor board 20, a size and a position of the wiring layer present in the sensor board 20, etc., are not limited to those illustrated in FIG. 1A. The logic circuit of the logic board 41 and the solid-state imaging element 22 of the sensor board 20 are electrically coupled with each other via the wiring layers 32 to 38 and the wiring layers 23 to 26.

### [Method of Manufacturing Solid-State Imaging Device 1]

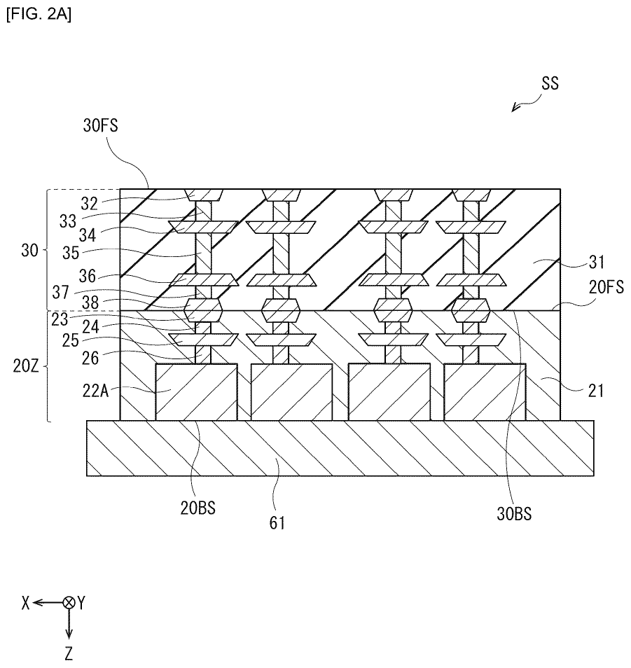

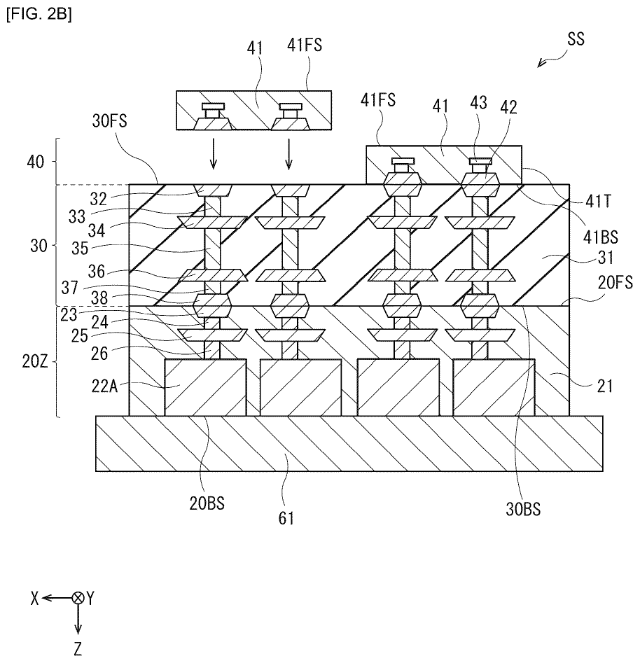

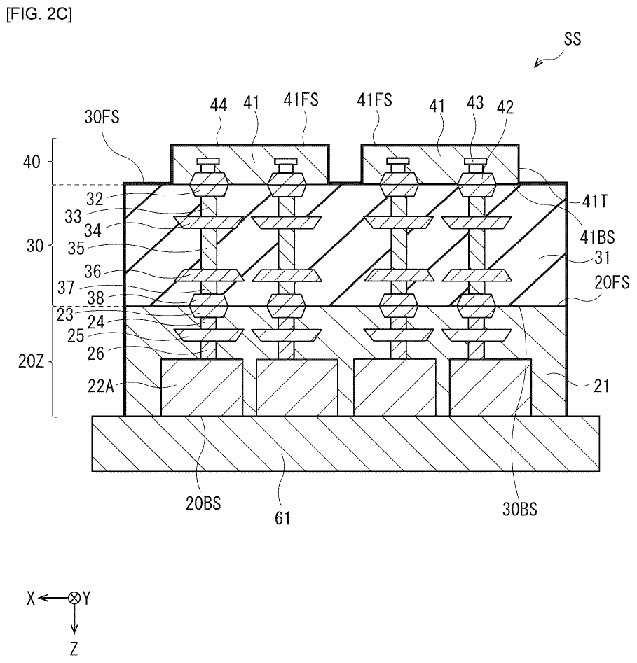

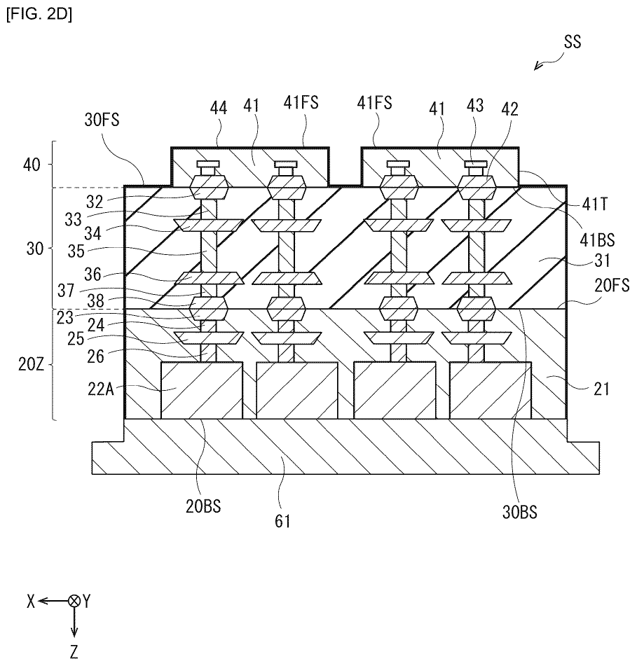

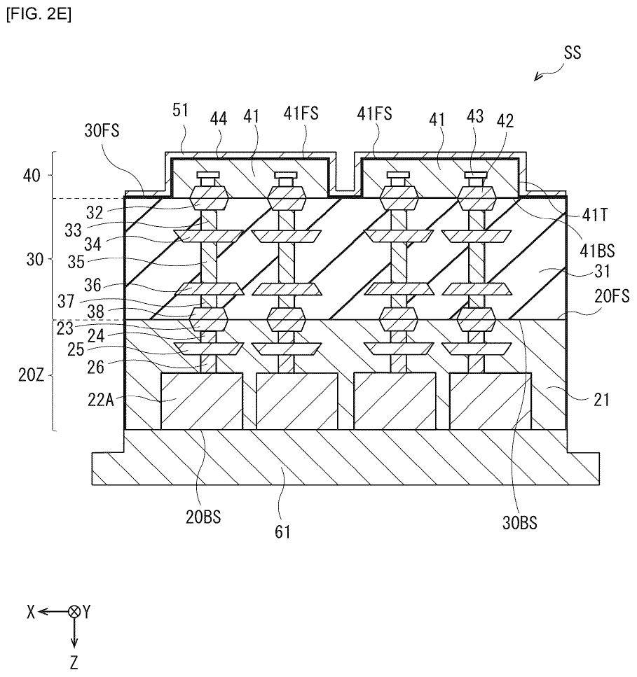

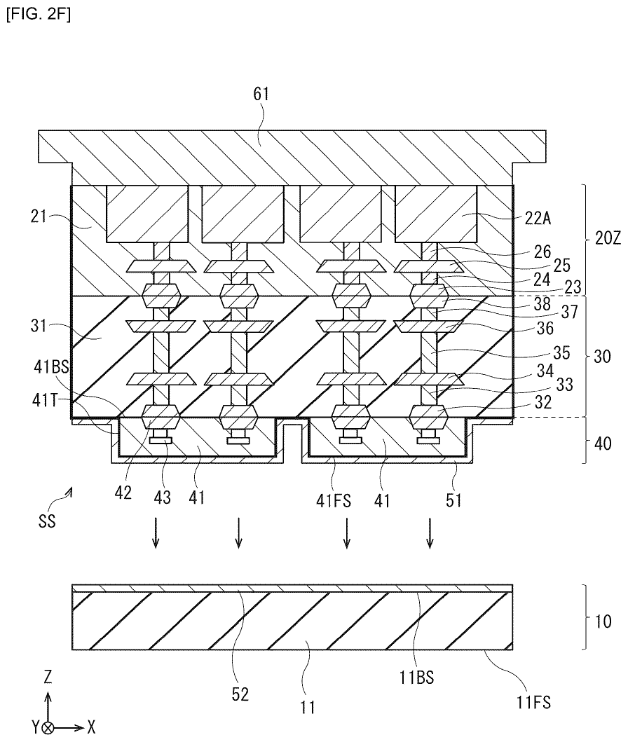

Next, a description is given of a method of manufacturing the solid-state imaging device 1, with reference to FIGS. 2A to 2G. Each of FIGS. 2A to 2G is a cross-sectional diagram illustrating one step of the method of manufacturing the solid-state imaging device 1, and corresponds to FIG. 1A. It is to be noted that FIGS. 2A to 2F exemplarily illustrate a process of manufacturing one solid-state imaging device 1, but in practice, a plurality of solid-state imaging devices 1 is collectively formed on a single wafer (the support board 11) as illustrated in FIG. 2G, and is thereafter cut for each solid-state imaging device 1.

First, as illustrated in FIG. 2A, a back surface 20BS of a sensor board 20Z is fixed to a support board 61. A configuration of the sensor board 20Z is substantially the same as a configuration of the sensor board 20 except that the sensor board 20Z includes, out of the solid-state imaging element 22, the photodiode 22A, but does not include the protective film 22B, the color filter 22C, and the microlens 22D. Thereafter, the back surface 30BS of the intermediate layer 30 is bonded to the front surface 20FS of the sensor board 20Z by a WoW (Wafer on Wafer) stacking technique. In this case, the wiring layer 23 and the wiring layer 38 are directly bonded to each other.

Thereafter, as illustrated in FIG. 2B, a separately prepared logic board 41 is bonded to the front surface 30FS of the intermediate layer 30 by a CoW (Chip on Wafer) stacking technique. Thus, a stack SS is obtained. Thereafter, the logic board 41 is polished as needed to adjust a thickness of the logic board 41. In a case of disposing the plurality of logic boards 41, height positions of the front surfaces 41FS of the plurality of logic boards 41 are adjusted so as to be aligned with each other.

Thereafter, as illustrated in FIG. 2C, the insulating layer 44 is formed so as to cover at least the front surface 30FS of the intermediate layer 30, and the end surface 41T and the front surface 41FS of the logic board 41.

Thereafter, as illustrated in FIG. 2D, trimming is performed along an outline of the stack of the sensor board 20Z, the intermediate layer 30, and the logic layer 40, and a peripheral part, of the support board 61, along the outline of the stack SS is dug down in a thickness direction to reduce a thickness thereof. This is to prevent a defect such as the support board 61 being chipped in an unintended shape when cutting into individual solid-state imaging devices 1 is performed.

Thereafter, as illustrated in FIG. 2E, the metal film 51 is further formed on a part, of the insulating layer 44, covering the front surface 30FS of the intermediate layer 30 and the end surface 41T and the front surface 41FS of the logic board 41. In this case, forming the metal film 51 by the ALD method makes it possible to obtain the metal film 51 having a more uniform thickness.

Thereafter, as illustrated in FIG. 2F, the metal film 52 is formed on the back surface 11BS, which is flat, of the support board 11, following which the metal film 51 and the metal film 52 are butted to each other, and the metal film 51 and the metal film 52 are bonded to each other by pressure bonding at room temperature. Alternatively, the metal film 51 and the metal film 52 may be heated and bonded to each other by thermal compression bonding. Thereafter, the support board 61 is polished to reduce the thickness thereof, following which the protective film 22B, the color filter 22C, and the microlens 22D are sequentially formed on the photodiode 22A to form the solid-state imaging element 22.

As described above, the plurality of solid-state imaging devices 1 is formed on one support board 11, as illustrated in FIG. 2G. Thereafter, the thickness of the support board 11 is processed to have a predetermined thickness by polishing the front surface 11FS of the support board 11 as needed. Lastly, a dicing blade or the like is used to perform cutting at a position indicated by a dashed line illustrated in FIG. 2G, thereby cutting out the plurality of solid-state imaging devices 1. Thus, the manufacturing of the solid-state imaging device 1 is completed.

### [Workings and Effects of Solid-State Imaging Device 1]

As described above, in the solid-state imaging device 1 of the present embodiment, the hollow V is provided so as to surround at least a portion of the periphery of the logic board 41 along the XY plane that is orthogonal to the stacking direction of the logic board 41 and the sensor board 20. Thus, the hollow V serves as a heatsink, and the heat of the logic board 41 is efficiently released. This makes it possible to mitigate an influence on operation performance of the solid-state imaging device 1, the influence being attributed to a dark current caused by temperature rise of the logic board 41. It is therefore possible to ensure high operation reliability in the solid-state imaging device 1. Further, the solid-state imaging device 1 of the present embodiment has a high heat dissipation property, which is also advantageous for further high integration.

Further, in the solid-state imaging device 1, the hollow V is also provided in the space between the two adjacent logic boards 41, which makes it possible to release the heat of each logic board 41 more efficiently to the outside via the hollow V.

Further, in the solid-state imaging device 1, the hollow V communicates with the outside, which makes it possible to introduce the outside air into the hollow V and discharge the outside air, and to further enhance the heat dissipation property.

Further, in the solid-state imaging device 1, the end surface 41T and the front surface 41FS of the logic board 41 are continuously covered by the metal film 51, which also makes it possible to efficiently release the heat of the logic board 41 via the metal film 51. In addition, the metal film 52 is also provided on the back surface 11BS of the support board 11 so that the metal film 51 and the metal film 52 are bonded to each other, which makes it possible to achieve a further higher heat dissipation property. Moreover, the solid-state imaging device 1 includes, even though the hollow V is present therein, the metal frame 50 including the metal film 51 and the metal film 52 bonded to each other. This makes it possible to prevent light traveling through the front surface 11FS from entering the sensor board 20. This also makes it possible for the support layer 10 to firmly support the logic board 41, the intermediate layer 30, and the sensor board 20.

### 2. Modification Examples of First Embodiment

### [Configuration of Solid-State Imaging Device 1A]

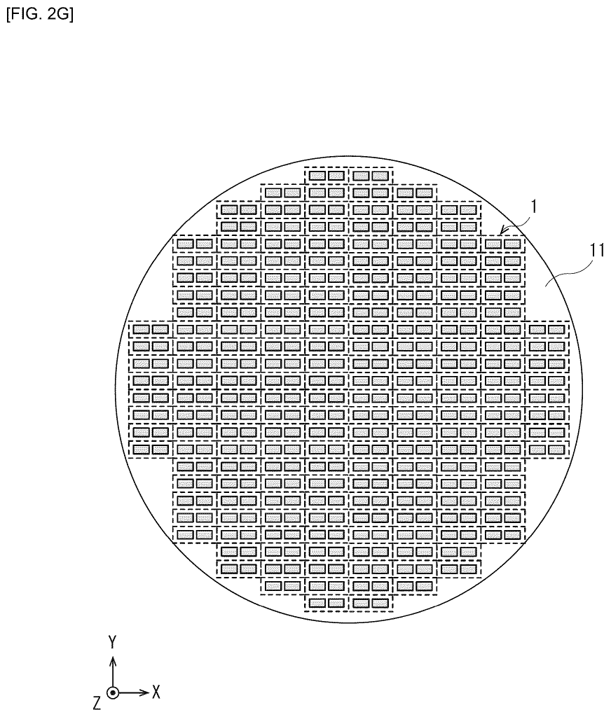

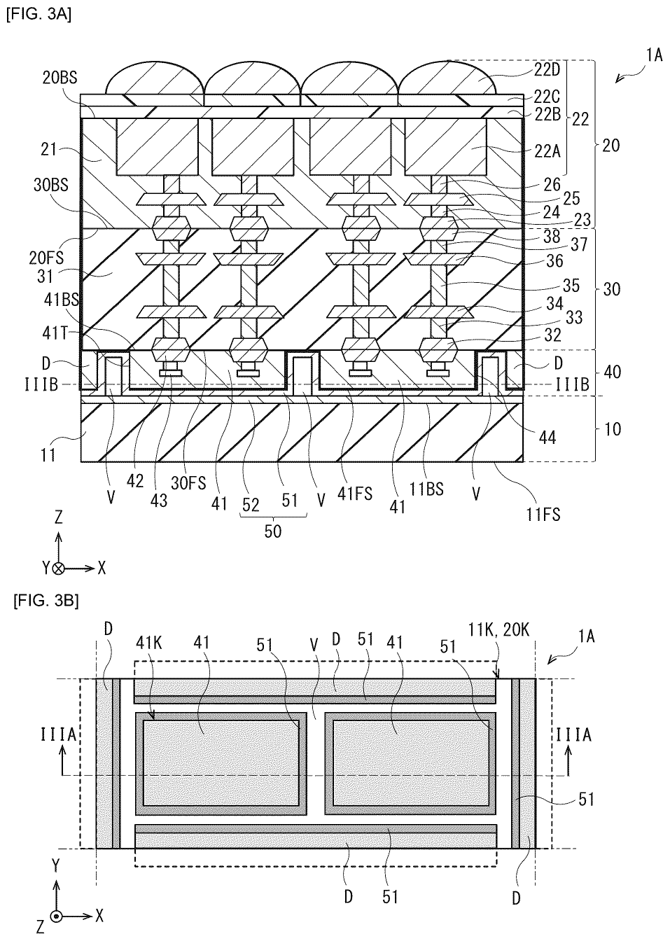

FIG. 3A is a cross-sectional diagram illustrating a cross-sectional configuration example of a solid-state imaging device 1A according to a first modification example (hereinafter referred to as Modification Example 1-1) of the present embodiment, and corresponds to FIG. 1A illustrating the solid-state imaging device 1 according to the first embodiment described above. Further, FIG. 3B is a plan diagram illustrating a planar configuration example of the solid-state imaging device 1A, and corresponds to FIG. 1B illustrating the solid-state imaging device 1 according to the first embodiment described above. FIG. 3A corresponds to a cross-sectional diagram of a stack in an arrow direction along a cutting line IIIA-IIIA illustrated in FIG. 3B. Further, FIG. 3B corresponds to a horizontal cross-sectional diagram at a height position indicated by a dashed line IIIB in FIG. 3A. It is to be noted that, in FIG. 3B, a two-dot chain line indicates a boundary between the plurality of solid-state imaging devices 1A adjacent to each other in a state prior to being divided into individual solid-state imaging devices 1A.

### [Workings and Effects of Solid-State Imaging Device 1A]

As illustrated in FIG. 3A, in the solid-state imaging device 1A of Modification Example 1-1, a dummy board D is disposed so as to be adjacent to the logic board 41 in the logic layer 40. The dummy board D is disposed so as to straddle a border with another adjacent solid-state imaging device 1A. It is thus possible that in the solid-state imaging device 1A, the logic board 41, the intermediate layer 30, and the sensor board 20 are further firmly supported by the support layer 10 as compared with the solid-state imaging device 1. Accordingly, when the plurality of solid-state imaging devices 1A formed on one support board 11 is to be cut into individual solid-state imaging devices 1A by a dicing blade or the like, it is possible to cut more accurately and smoothly than when no dummy board D is provided.

In addition, the hollow V is provided so as to surround at least a portion of the periphery of the logic board 41 also in the solid-state imaging device 1A, which efficiently releases heat of the logic board 41. It is therefore possible to achieve effects similar to those of the solid-state imaging device 1.

### [Configuration of Solid-State Imaging Device 1B]

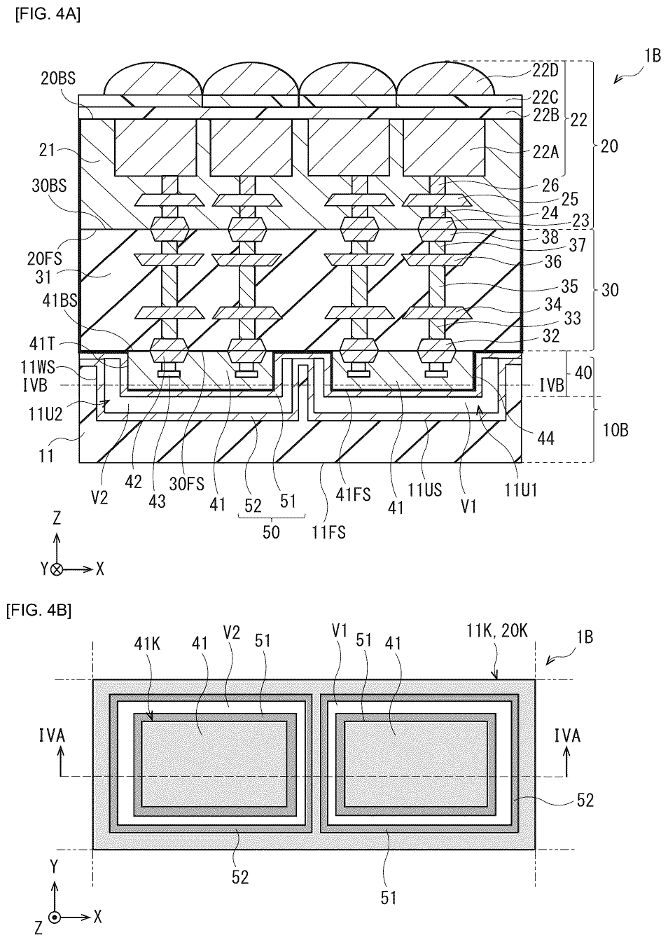

FIG. 4A is a cross-sectional diagram illustrating a cross-sectional configuration example of a solid-state imaging device 1B according to a second modification example (hereinafter referred to as Modification Example 1-2) of the present embodiment, and corresponds to FIG. 1A illustrating the solid-state imaging device 1 according to the first embodiment described above. Further, FIG. 4B is a plan diagram illustrating a planar configuration example of the solid-state imaging device 1B, and corresponds to FIG. 1B illustrating the solid-state imaging device 1 according to the first embodiment described above. FIG. 4A corresponds to a cross-sectional diagram of a stack in an arrow direction along a cutting line IVA-IVA illustrated in FIG. 4B. Further, FIG. 4B corresponds to a horizontal cross-sectional diagram at a height position indicated by a dashed line IVB in FIG. 4A.

In the solid-state imaging device 1 according to the first embodiment described above, the logic layer 40 is stacked on the support layer 10 in which the metal film 52 that is flat is provided on the support board 11 having a flat plate shape. In contrast, the solid-state imaging device 1B according to Modification Example 1-2 employs a support layer 10B instead of the support layer 10. Specifically, a concave portion 11U1 and a concave portion 11U2 are provided in the support board 11, and the logic board 41 is accommodated in each of the concave portions 11U1 and 11U2. In the solid-state imaging device 1B, it is sufficient that at least a portion of the logic board 41 in the thickness direction is accommodated in the concave portions 11U1 and 11U2. That is, in a state in which the solid-state imaging device 1B is viewed along the XY plane, the support layer 10B and at least a portion of the logic layer 40 overlap each other. An inner surface of each of the concave portions 11U1 and 11U2 is covered with the metal film 52. Here, a portion, of the metal film 52, that covers a bottom surface 11US and a side surface 11WS of each of the concave portions 11U1 and 11U2 is spaced apart from a portion, of the metal film 51, that covers the front surface 41FS and the end surface 41T of the logic board 41, and this forms hollows V1 and V2. That is, the hollows V1 and V2 are also present between the logic board 41 and the support board 11. It is to be noted that the hollow V1 and the hollow V2 are each present in the periphery of corresponding one of the different logic boards 41, and are separated from each other.

### [Method of Manufacturing Solid-State Imaging Device 1B]

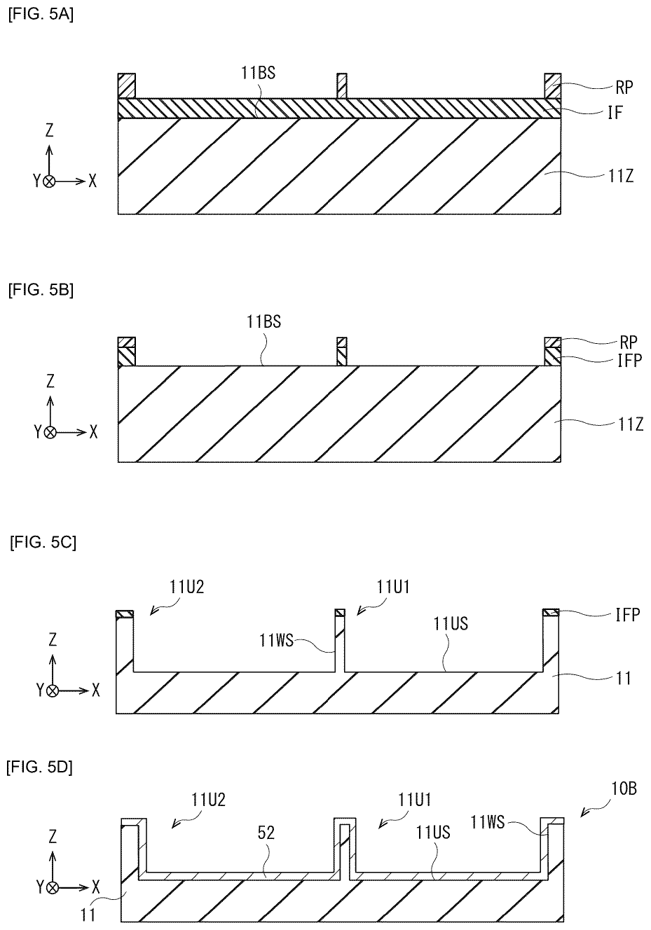

Next, a description is given of a method of manufacturing the solid-state imaging device 1B with reference to FIGS. 5A to 5D. Here, a method of manufacturing the support layer 10B of the solid-state imaging device 1B will be described in detail. Each of FIGS. 5A to 5D is a cross-sectional diagram illustrating one step of the method of manufacturing the support layer 10B. It is to be noted that FIGS. 5A to 5D illustrate a process of manufacturing the support layer 10B including two concave portions 11U1 and 11U2; however, the number of concave portions is not limited thereto.

First, as illustrated in FIG. 5A, a silicon board 11Z, for example, is prepared, following which an inorganic film IF including SiO₂ or the like is formed so as to entirely cover the back surface 11BS. Thereafter, a resist film is formed so as to entirely cover the inorganic film IF, following which a resist film is selectively removed by a photolithography method or the like to obtain a resist pattern RP.

Thereafter, as illustrated in FIG. 5B, the inorganic film IF is patterned by a selective etching process using the resist pattern RP as a mask to obtain an inorganic film pattern IFP. As a result, a portion of the back surface 11BS is exposed.

Thereafter, as illustrated in FIG. 5C, an exposed part of the silicon board 11Z is dug down by a selective etching process using the inorganic film pattern IFP as a mask to thereby obtain the support board 11 including the concave portions 11U1 and 11U2.

Lastly, as illustrated in FIG. 5D, the inorganic film pattern IFP is removed, following which the metal film 52 is formed so as to cover the entire support board 11 including the bottom surface 11US and the side surface 11WS of each of the concave portions 11U1 and 11U2.

Thus, the manufacturing of the support layer 10B is completed. Thereafter, it is possible to manufacture the solid-state imaging device 1B similarly as the solid-state imaging device 1 described in the first embodiment.

### [Workings and Effects of Solid-State Imaging Device 1B]

In the solid-state imaging device 1B according to Modification Example 1-2, the concave portion 11U1 and the concave portion 11U2 are provided in the support board 11, and the logic board 41 is accommodated in each of the concave portions 11U1 and 11U2. Accordingly, it is possible to achieve a high heat dissipation property while improving a mechanical strength as compared with the solid-state imaging device 1. In addition, in the solid-state imaging device 1B, the hollows V1 and V2 are also present between the logic board 41 and the support board 11. This increases a surface area of the logic board 41 exposed to the hollows V1 and V2, and makes it possible to further enhance the heat dissipation property.

### [Configuration of Solid-State Imaging Device 1C]

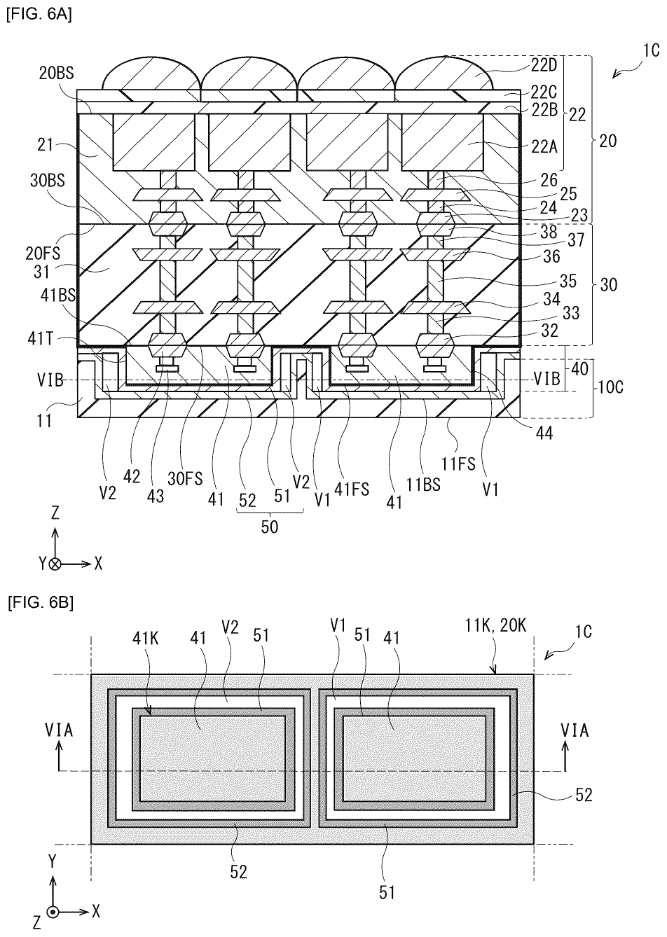

FIG. 6A is a cross-sectional diagram illustrating a cross-sectional configuration example of a solid-state imaging device 1C according to a third modification example (hereinafter referred to as Modification Example 1-3) of the present embodiment, and corresponds to FIG. 1A illustrating the solid-state imaging device 1 according to the first embodiment described above. Further, FIG. 6B is a plan diagram illustrating a planar configuration example of the solid-state imaging device 1C, and corresponds to FIG. 1B illustrating the solid-state imaging device 1 according to the first embodiment described above. FIG. 6A corresponds to a cross-sectional diagram of a stack in an arrow direction along a cutting line VIA-VIA illustrated in FIG. 6B. Further, FIG. 6B corresponds to a horizontal cross-sectional diagram at a height position indicated by a dashed line VIB in FIG. 6A.

The solid-state imaging device 1C according to Modification Example 1-3 employs a support layer 10C instead of the support layer 10. Specifically, the concave portion 11U1 and the concave portion 11U2 are provided in the support board 11, and the logic board 41 is accommodated in each of the concave portions 11U1 and 11U2. It is to be noted that in the solid-state imaging device 1C, a portion, of the metal film 52, that covers the bottom surface 11US of each of the concave portions 11U1 and 11U2 is abutted against a portion, of the metal film 51, that covers the front surface 41FS of the logic board 41. In contrast, a portion, of the metal film 52, that covers the side surface 11WS of each of the concave portions 11U1 and 11U2 is spaced apart from a portion, of the metal film 51, that covers the end surface 41T of the logic board 41, and this forms the hollows V1 and V2. Except for that, the configuration of the solid-state imaging device 1C is substantially the same as the configuration of the solid-state imaging device 1B.

### [Method of Manufacturing Solid-State Imaging Device 1C]

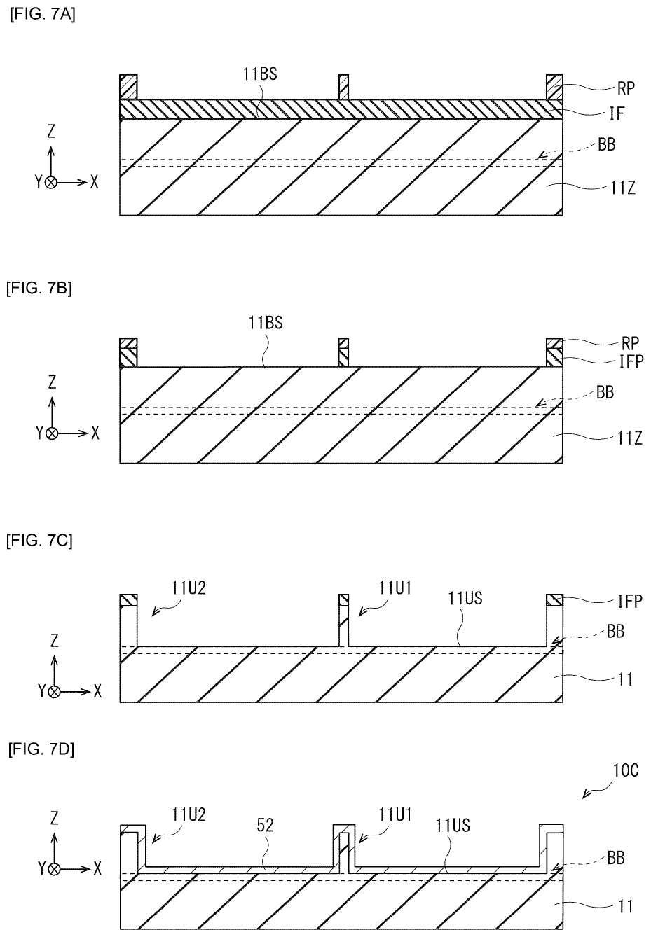

Next, a description is given of a method of manufacturing the solid-state imaging device 1C with reference to FIGS. 7A to 7D. Here, a method of manufacturing the support layer 10C of the solid-state imaging device 1C will be described in detail. Each of FIGS. 7A to 7D is a cross-sectional diagram illustrating one step of the method of manufacturing the support layer 10C. It is to be noted that FIGS. 7A to 7D illustrate a process of manufacturing the support layer 10C including two concave portions 11U1 and 11U2; however, the number of concave portions is not limited thereto.

First, as illustrated in FIG. 7A, the silicon board 11Z, for example, is prepared, following which an inorganic film IF including SiO₂ or the like is formed so as to entirely cover the back surface 11BS. However, the silicon board 11Z includes, in a portion thereof in the thickness direction, a high-concentration impurity layer BB including boron (B) or the like. Thereafter, a resist film is formed so as to entirely cover the inorganic film IF, following which a resist film is selectively removed by a photolithography method or the like to obtain a resist pattern RP.

Thereafter, as illustrated in FIG. 7B, the inorganic film IF is patterned by a selective etching process using the resist pattern RP as a mask to obtain an inorganic film pattern IFP. As a result, a portion of the back surface 11BS is exposed.

Thereafter, as illustrated in FIG. 7C, an exposed part of the silicon board 11Z is dug down by a selective etching process using the inorganic film pattern IFP as a mask to thereby obtain the support board 11 including the concave portions 11U1 and 11U2. At this time, the high-concentration impurity layer BB serves as an etching stopper, and a depth of each of the concave portions 11U1 and 11U2 is controlled with high accuracy.

Lastly, as illustrated in FIG. 7D, the inorganic film pattern IFP is removed, following which the metal film 52 is formed so as to cover the entire support board 11 including the bottom surface 11US and the side surface 11WS of each of the concave portions 11U1 and 11U2.

Thus, the manufacturing of the support layer 10C is completed. Thereafter, it is possible to manufacture the solid-state imaging device 1C similarly as the solid-state imaging device 1 described in the first embodiment.

### [Workings and Effects of Solid-State Imaging Device 1C]

In the solid-state imaging device 1C according to Modification Example 1-3, the concave portion 11U1 and the concave portion 11U2 are provided in the support board 11, and the logic board 41 is accommodated in each of the concave portions 11U1 and 11U2. Accordingly, it is possible to achieve a high heat dissipation property while improving a mechanical strength as compared with the solid-state imaging device 1. In addition, in the solid-state imaging device 1B, the portion, of the metal film 52, that covers the bottom surface 11US of each of the concave portions 11U1 and 11U2 is abutted against the portion, of the metal film 51, that covers the front surface 41FS of the logic board 41. Accordingly, it is possible to achieve reduction in thickness of the support layer 10C as compared with the support layer 10 or the support layer 10B. In addition, the heat of the logic board 41 is efficiently released via the metal film 51 and the metal film 52.

### [Configuration of Solid-State Imaging Device 1D]

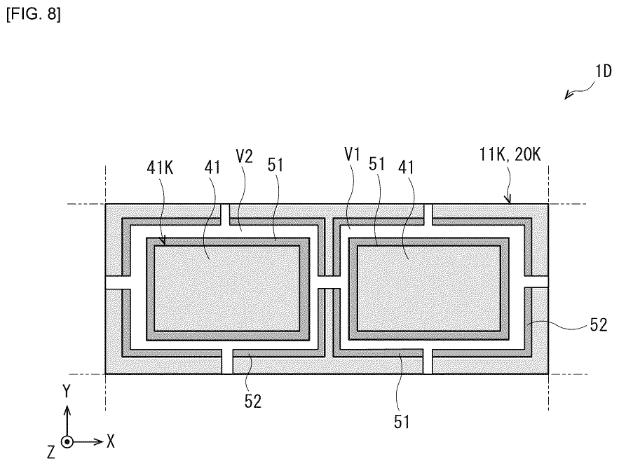

FIG. 8 is a plan diagram illustrating a planar configuration example of a solid-state imaging device 1D according to a fourth modification example (hereinafter referred to as Modification Example 1-4) of the present embodiment, and corresponds to FIG. 1B illustrating the solid-state imaging device 1 according to the first embodiment described above. In the solid-state imaging device 1D according to the fourth modification example, the hollows V1 and V2 communicate with each other, and each communicate with the outside. This makes it possible to further enhance the heat dissipation property.

### 3. Second Embodiment

### [Configuration of Solid-State Imaging Device 2]

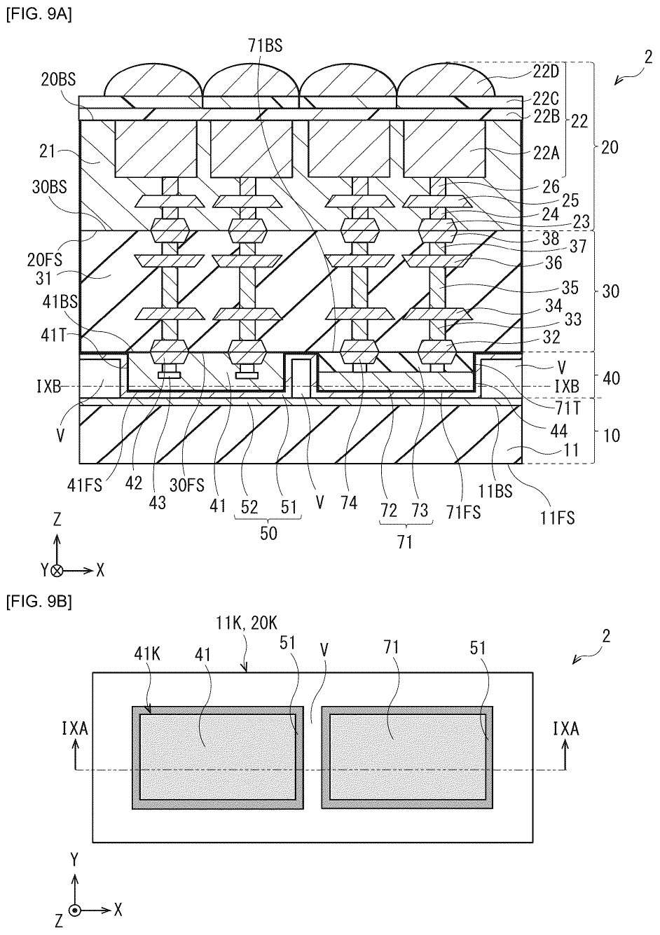

FIGS. 9A and 9B each schematically illustrate a configuration example of a solid-state imaging device 2 according to a second embodiment of the present disclosure. FIG. 9A illustrates a cross-sectional configuration example of the solid-state imaging device 2, and FIG. 9B illustrates a planar configuration example of the solid-state imaging device 2. FIG. 9A corresponds to a cross-sectional diagram of a stack in an arrow direction along a cutting line IXA-IXA illustrated in FIG. 9B. Further, FIG. 9B corresponds to a horizontal cross-sectional diagram at a height position indicated by a dashed line IXB in FIG. 9A.

In the solid-state imaging device 1 according to the first embodiment, the logic layer 40 includes one or more logic boards 41. In contrast, in the solid-state imaging device 2 according to the present embodiment, the logic layer 40 further includes a heat dissipation board 71 in addition to the logic board 41. The heat dissipation board 71 is provided at a position adjacent to the logic board 41 along the XY plane, and has an area smaller than the area of the sensor board 20 in the XY plane. The hollow V is also provided in a periphery of the heat dissipation board 71. The hollow V is provided so as to surround the periphery of the heat dissipation board 71 along the XY plane. Accordingly, the hollow V is also present between the heat dissipation board 71 and the adjacent logic board 41. It is to be noted that the number of the heat dissipation boards 71 may be more than two.

The heat dissipation board 71 has a heat conductivity higher than, for example, a heat conductivity of the logic board 41. In addition, the heat dissipation board 71 may have a heat conductivity higher than a heat conductivity of the sensor board 20. The heat dissipation board 71 includes, for example, a metal layer 72, an insulating layer 73 stacked on the metal layer 72, and wiring 74 embedded in the insulating layer 73. The metal layer 72 extends along the XY plane. The metal layer 72 may extend, for example, throughout the heat dissipation board 71. The metal layer 72 includes a simple substance of a metal element having a relatively high heat conductivity, such as Ag (silver), Al (aluminum), Cu (copper), Ti (titanium), or W (tungsten), or an alloy including those metal elements. The insulating layer 73 includes an insulating material such as aluminum oxide or the like. Further, a portion of the wiring 74 is exposed to a back surface 71BS of the heat dissipation board 71. The wiring 74 does not configure an electric circuit such as a logic circuit, and is what is called dummy wiring. The wiring layer 74 includes, for example, Cu (copper). The back surface 71BS of the heat dissipation board 71 is bonded to the front surface 30FS of the intermediate layer 30. A front surface 71FS and an end surface 71T of the heat dissipation board 71, as with the front surface 41FS and the end surface 41T of the logic board 41, may be covered with the metal film 52.

### [Method of Manufacturing Solid-State Imaging Device 2]

A method of manufacturing the solid-state imaging device 2 is substantially the same as the method of manufacturing the solid-state imaging device 1 according to the first embodiment described above, except that when some logic boards 41 are to be bonded to the front surface 30FS of the intermediate layer 30, one or more heat dissipation boards 71 instead of one or more of the logic boards 41 are to be bonded to the front surface 30FS of the intermediate layer 30.

### [Workings and Effects of Solid-State Imaging Device 2]

As described above, in the solid-state imaging device 2 of the present embodiment, the heat dissipation board 71 having a heat conductivity higher than the heat conductivity of the logic board 41 is provided as a third device board over the sensor board 20, which makes it possible to release the heat of the logic board 41 efficiently to the outside.

### 4. Modification Examples of Second Embodiment

### [Configuration of Solid-State Imaging Device 2A]

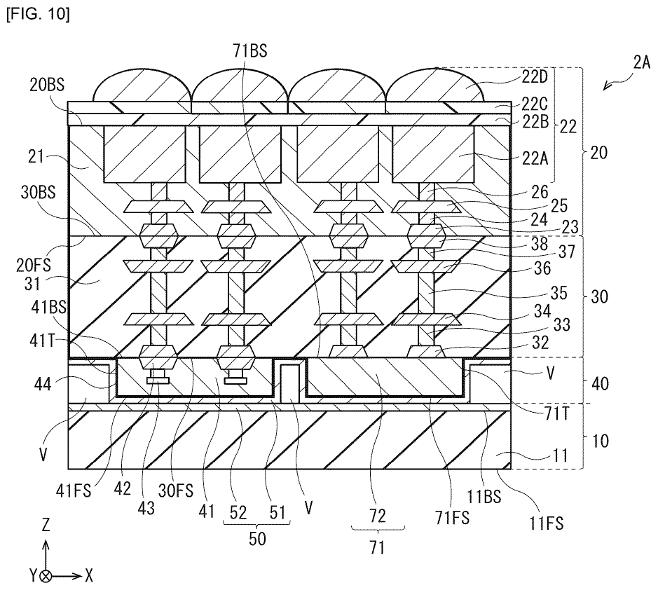

FIG. 10 is a cross-sectional diagram illustrating a cross-sectional configuration example of a solid-state imaging device 2A according to a first modification example (hereinafter referred to as Modification Example 2-1) of the present embodiment, and corresponds to FIG. 9A illustrating the solid-state imaging device 2 according to the second embodiment described above.

As illustrated in FIG. 10, in the solid-state imaging device 2A of Modification Example 2-1, the heat dissipation board 71 includes only the metal layer 72. Except for that, the configuration of the solid-state imaging device 2A is substantially the same as the configuration of the solid-state imaging device 2 of the second embodiment described above.

### [Workings and Effects of Solid-State Imaging Device 2A]

In the solid-state imaging device 2A of Modification Example 2-1, the heat dissipation board 71 includes only the metal layer 72, which makes it possible to increase a volume of the metal layer 72 as compared with the solid-state imaging device 2 according to the second embodiment described above. This makes it possible to further enhance heat dissipation performance of the heat dissipation board 71. Accordingly, it possible to release the heat of the logic board 41 or the sensor board 20 more efficiently to the outside.

### [Configuration of Solid-State Imaging Device 2B]

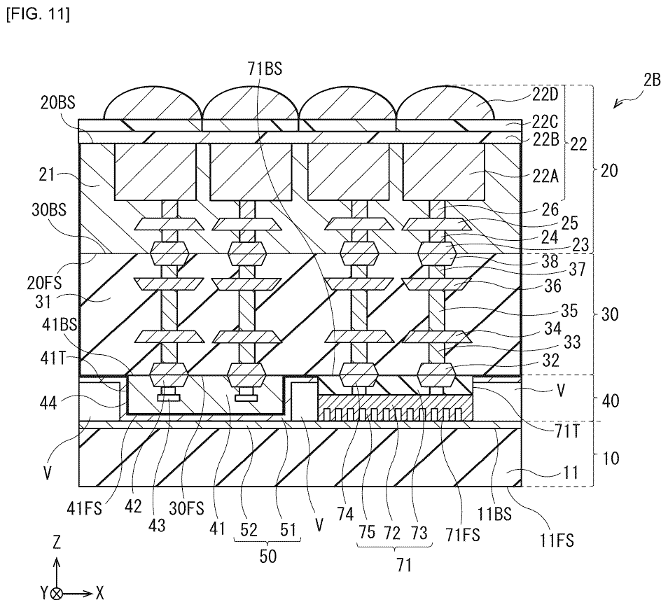

FIG. 11 is a cross-sectional diagram illustrating a cross-sectional configuration example of a solid-state imaging device 2B according to a second modification example (hereinafter referred to as Modification Example 2-2) of the present embodiment, and corresponds to FIG. 9A illustrating the solid-state imaging device 2 according to the second embodiment described above.

As illustrated in FIG. 11, in the solid-state imaging device 2B of Modification Example 2-2, the heat dissipation board 71 includes one or more fins 75 provided upright on the metal layer 72. Except for that, the configuration of the solid-state imaging device 2B is substantially the same as the configuration of the solid-state imaging device 2 of the second embodiment described above. It is to be noted that the fins 75 may be provided in an integrated manner with the metal layer 72. That is, the metal layer 72 may include the fin structure 75,

### [Workings and Effects of Solid-State Imaging Device 2B]

In the solid-state imaging device 2B of Modification Example 2-2, the heat dissipation board 71 includes the fin 75, which makes it possible to further improve the heat dissipation performance of the heat dissipation board 71 as compared with the solid-state imaging device 2 according to the second embodiment described above. Accordingly, it possible to release the heat of the logic board 41 or the sensor board 20 more efficiently to the outside.

### [Configuration of Solid-State Imaging Device 2C]

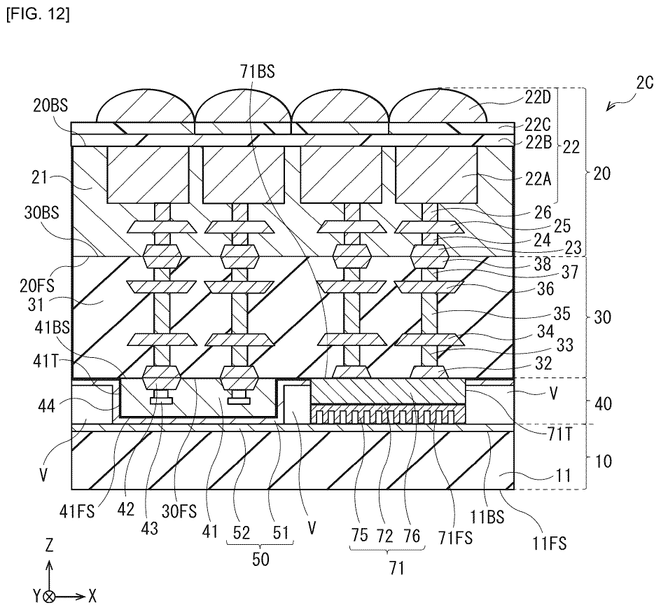

FIG. 12 is a cross-sectional diagram illustrating a cross-sectional configuration example of a solid-state imaging device 2C according to a third modification example (hereinafter referred to as Modification Example 2-3) of the present embodiment, and corresponds to FIG. 9A illustrating the solid-state imaging device 2 according to the second embodiment described above.

As illustrated in FIG. 12, in the solid-state imaging device 2C of Modification Example 2-3, the heat dissipation board 71 includes a cooling element 76 instead of the insulating layer 73 and the wiring 74. Except for that, the configuration of the solid-state imaging device 2C is substantially the same as the configuration of the solid-state imaging device 2B of Modification Example 2-2 described above. As the cooling element 76, a Peltier element may be used, for example. In a case where the cooling element 76 is, for example, the Peltier element, a path for supplying power that is necessary for an operation thereof may be provided.

### [Workings and Effects of Solid-State Imaging Device 2C]

In the solid-state imaging device 2C of Modification Example 2-3, the heat dissipation board 71 further includes the cooling element 76, which makes it possible to further improve the heat dissipation performance of the heat dissipation board 71 as compared with the solid-state imaging device 2B of Modification Example 2-2 described above. Accordingly, it possible to release the heat of the logic board 41 or the sensor board 20 more efficiently to the outside.

It is to be noted that in the solid-state imaging device 2 according to the second embodiment described above, the cooling element 76 may be provided instead of the insulating layer 73 and the wiring 74. Further, in the solid-state imaging device 2A of Modification Example 2-1 described above, the cooling element 76 may be provided instead of the insulating layer 73 and the wiring 74.

### 5. Third Embodiment

### [Configuration of Solid-State Imaging Device 3]

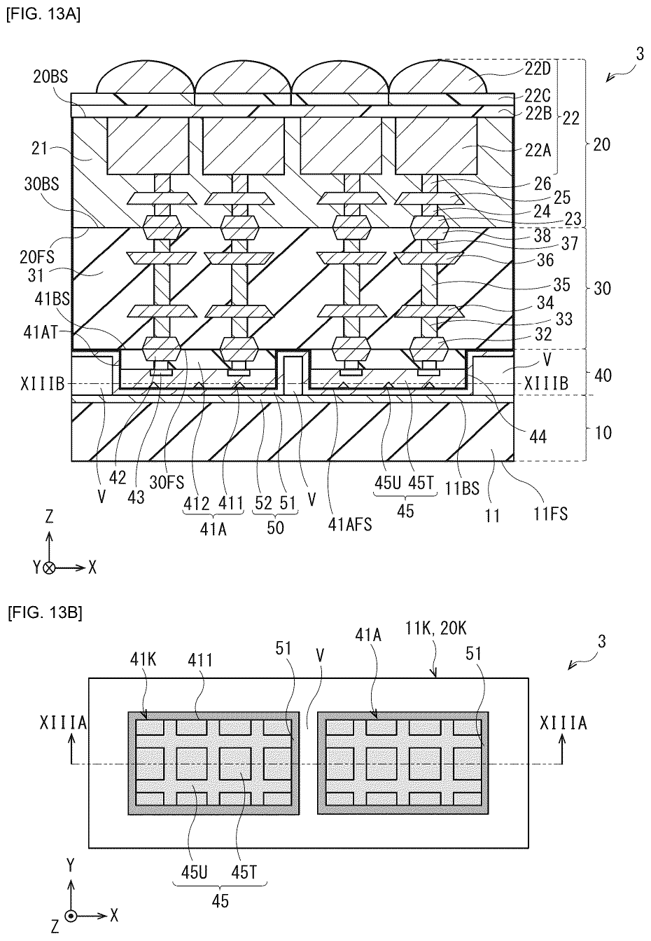

FIGS. 13A and 13B each schematically illustrate a configuration example of a solid-state imaging device 3 according to a third embodiment of the present disclosure. FIG. 13A illustrates a cross-sectional configuration example of the solid-state imaging device 3, and FIG. 13B illustrates a planar configuration example of the solid-state imaging device 3. FIG. 13A corresponds to a cross-sectional diagram of a stack in an arrow direction along a cutting line XIIIA-XIIIA illustrated in FIG. 13B. Further, FIG. 13B corresponds to a horizontal cross-sectional diagram at a height position indicated by a dashed line XIIIB in FIG. 13A.

In the solid-state imaging device 3 according to the present embodiment, the logic layer 40 includes a logic board 41A instead of the logic board 41. Except for that, the configuration of the solid-state imaging device 3 is substantially the same as the configuration of the solid-state imaging device 1. Accordingly, the logic board 41A of the solid-state imaging device 3 will be mainly described in the following description, components of the solid-state imaging device 3 that are the same as those of the solid-state imaging device 1 are denoted by the same reference signs, and description thereof will be omitted as appropriate.

As illustrated in FIGS. 13A and 13B, the logic board 41A includes a semiconductor substrate 411, and an insulating layer 412 stacked on the semiconductor substrate 411. The semiconductor element 43 is provided in the semiconductor substrate 411. The wiring layer 42 is provided in the insulating layer 412. In addition, in the logic board 41A, at least a portion of a surface other than a back surface 41BS of the semiconductor substrate 411 has a concave-convex structure 45. FIGS. 13A and 13B illustrates an example of a case where a front surface 41AFS is a surface having the concave-convex structure 45. The concave-convex structure 45 includes a concave portion 45U and a convex portion 45T. The back surface 41BS is an opposed surface that is opposed to the front surface 20FS of the sensor board 20 and is also a bonding surface that is to be bonded to the front surface 30FS of the intermediate layer 30. In the configuration example illustrated in each of FIGS. 13A and 13B, for example, a plurality of concave portions 45U each extending in an X axis direction and a plurality of concave portions 45U each extending in a Y axis direction are provided so as to intersect each other. That is, in the front surface 41AFS of the semiconductor substrate 411, the concave portions 45U are provided in a lattice pattern in the XY plane. Further, as illustrated in FIG. 13A, a cross-sectional shape of the concave portion 45U is, for example, a substantially V shape. However, the cross-sectional shape of the concave portion 45U is not limited thereto, and various cross-sectional shapes other than the substantially V shape may be employed, examples of which include a rectangular shape, an inverted trapezoidal shape, a semicircular shape, a semielliptical shape, and a U shape.

In addition, the concave-convex structure 45 referred to in the present embodiment has a front surface roughness larger than a front surface roughness of a front surface planarized by CMP (chemical mechanical polishing), for example. The front surface 41AFS, which is a surface of the logic board 41A having a concave-convex structure 45, has an arithmetic mean roughness Ra value greater than 0.2 nm or has a root mean square roughness Rms value greater than 0.25 nm. Further, the hollow V is provided in a periphery of the logic board 41A. At least a portion of the hollow V is defined by the metal film 51 covering the logic board 41A. The metal film 51 continuously covers an end surface 41AT of the logic board 41A and the front surface 41AFS of the logic board 41A.

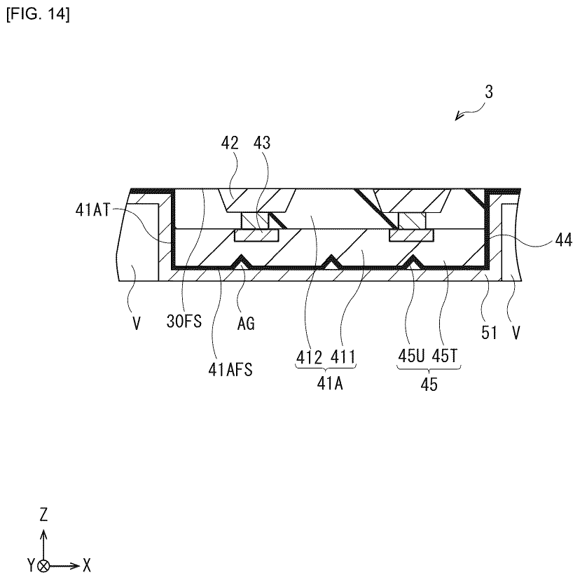

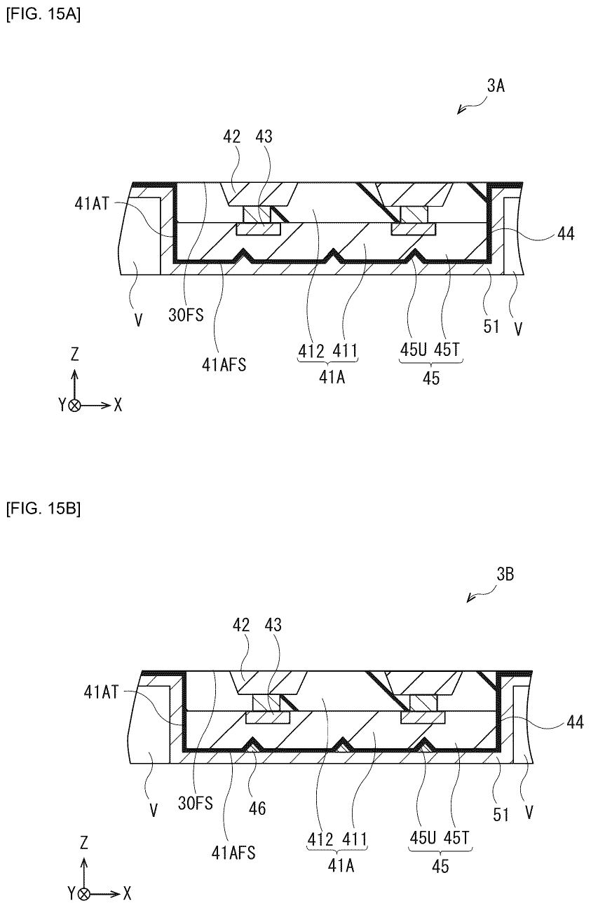

FIG. 14 is an enlarged cross-sectional diagram illustrating in an enlarged manner the logic board 41A illustrated in FIG. 13A. As illustrated in FIG. 14, in the solid-state imaging device 3 of the present embodiment, a gap AG is provided between the front surface 41FS of the logic board 41A and the metal film 51. Specifically, a plurality of the gaps AG is present in the respective plurality of concave portions 45U.

### [Method of Manufacturing Solid-State Imaging Device 3]

A method of manufacturing the solid-state imaging device 3 is substantially the same as the method of manufacturing the solid-state imaging device 1 according to the first embodiment described above, except that the logic board 41 is bonded to the front surface 30FS of the intermediate layer 30, and the logic board 41 is polished as needed to adjust the thickness of the logic board 41 (see FIG. 2B), following which the concave-convex structure 45 is formed by at least one of dry or wet etching.

### [Workings and Effects of Solid-State Imaging Device 3]

As described above, in the solid-state imaging device 3 of the present embodiment, the logic board 41A has the concave-convex structure 45 in at least a portion of the surface other than the back surface 41BS of the semiconductor substrate 411, which increases a surface area of the logic board 41A as compared with the logic board 41 of the solid-state imaging device 1 according to the first embodiment, for example. Thus, according to the solid-state imaging device 3, the logic board 41A has a high heat dissipation property, and it is possible to release the heat of the logic board 41A or the sensor board 20 efficiently to the outside. In particular, the gap AG is provided between the front surface 41AFS of the logic board 41A and the metal film 51, which makes it possible to release the heat of the logic board 41A or the sensor board 20 more efficiently to the outside.

### 6. Modification Examples of Third Embodiment

### First Modification Example

### [Configuration of Solid-State Imaging Device 3A]

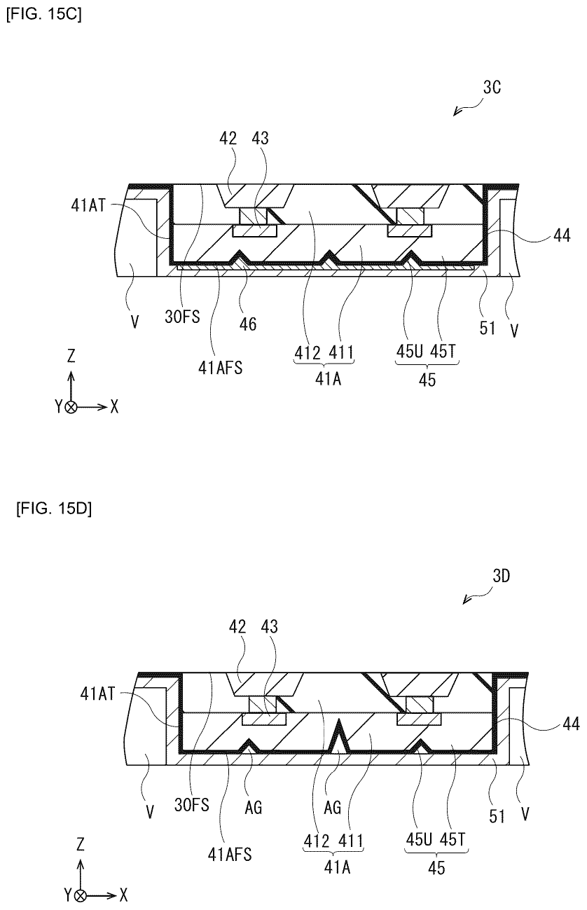

FIG. 15A is an enlarged cross-sectional diagram illustrating in an enlarged manner a cross-sectional configuration example of a portion of a solid-state imaging device 3A according to a first modification example (hereinafter referred to as Modification Example 3-1) of the present embodiment, and corresponds to FIG. 14 illustrating the solid-state imaging device 3 according to the third embodiment described above.

As illustrated in FIG. 15A, in the solid-state imaging device 3A of Modification Example 3-1, the metal film 51 is provided so as to also fill an inside of the concave portion 45U provided in the semiconductor substrate 411. Except for that, the configuration of the solid-state imaging device 3A is substantially the same as the configuration of the solid-state imaging device 3 of the third embodiment described above.

### [Workings and Effects of Solid-State Imaging Device 3A]

In the solid-state imaging device 3A of Modification Example 3-1, the metal film 51 is provided so as to also fill the concave portion 45U of the concave-convex structure 45, which makes it possible to increase a bonding strength between the metal film 51 and the logic board 41A.

### Second Modification Example

### [Configuration of Solid-State Imaging Device 3B]

FIG. 15B is an enlarged cross-sectional diagram illustrating in an enlarged manner a cross-sectional configuration example of a portion of a solid-state imaging device 3B according to a second modification example (hereinafter referred to as Modification Example 3-2) of the present embodiment, and corresponds to FIG. 14 illustrating the solid-state imaging device 3 according to the third embodiment described above.

As illustrated in FIG. 15B, in the solid-state imaging device 3B of Modification Example 3-2, a metal film 46 is provided so as to fill the inside of the concave portion 45U provided in the semiconductor substrate 411. Except for that, the configuration of the solid-state imaging device 3B is substantially the same as the configuration of the solid-state imaging device 3 of the third embodiment described above. A material included in the metal film 46 is different from a material included in the metal film 51. Specifically, usable as the material to be included in the metal film 46 is a metal material such as W (tungsten) having a higher light-shielding property as compared with the material (for example, copper) included in the metal film 51.

### [Workings and Effects of Solid-State Imaging Device 3B]

In the solid-state imaging device 3B of Modification Example 3-2, the concave portion 45U of the concave-convex structure 45 is filled with the metal film 46, which makes it possible to decrease an amount of unnecessary light entering the sensor board 20. It is therefore possible to improve operation reliability of the solid-state imaging device 3B.

### Third Modification Example

### [Configuration of Solid-State Imaging Device 3C]

FIG. 15C is an enlarged cross-sectional diagram illustrating in an enlarged manner a cross-sectional configuration example of a portion of a solid-state imaging device 3C according to a third modification example (hereinafter referred to as Modification Example 3-3) of the present embodiment, and corresponds to FIG. 14 illustrating the solid-state imaging device 3 according to the third embodiment described above.

As illustrated in FIG. 15C, in the solid-state imaging device 3C of Modification Example 3-3, the metal film 46 is provided so as to fill the inside of the concave portion 45U provided in the semiconductor substrate 411, and also to cover the convex portion 45T. Except for that, the configuration of the solid-state imaging device 3C is substantially the same as the configuration of the solid-state imaging device 3 of the third embodiment described above.

### [Workings and Effects of Solid-State Imaging Device 3C]

In the solid-state imaging device 3C of Modification Example 3-3, the metal film 46 is provided so as to fill the inside of the concave portion 45U and also to cover the convex portion 45T, which makes it possible to further decrease the amount of unnecessary light entering the sensor board 20 as compared with the solid-state imaging device 3B of Modification Example 3-2. It is therefore possible to further improve the operation reliability of the solid-state imaging device 3B.

### Fourth Modification Example

### [Configuration of Solid-State Imaging Device 3D]

FIG. 15D is an enlarged cross-sectional diagram illustrating in an enlarged manner a cross-sectional configuration example of a portion of a solid-state imaging device 3D according to a fourth modification example (hereinafter referred to as Modification Example 3-4) of the present embodiment, and corresponds to FIG. 14 illustrating the solid-state imaging device 3 according to the third embodiment described above.

As illustrated in FIG. 15D, in the solid-state imaging device 3D of Modification Example 3-4, two or more concave portions 45U having different depths are formed in the semiconductor substrate 411. Specifically, in the solid-state imaging device 3D, the depth of the concave portion 45U at a position overlapping with the semiconductor element 43 in the Z axis direction is made relatively shallow, and the depth of the concave portion 45U at a position not overlapping with the semiconductor element 43 in the Z axis direction is made relatively deep. Except for that, the configuration of the solid-state imaging device 3D is substantially the same as the configuration of the solid-state imaging device 3 of the third embodiment described above.

### [Workings and Effects of Solid-State Imaging Device 3D]

The solid-state imaging device 3D of Modification Example 3-4 has the above-described configuration, which further increases the surface area of the logic board 41A as compared with the solid-state imaging device 3 of the third embodiment described above (FIG. 14), for example. Thus, according to the solid-state imaging device 3D, the logic board 41A has a higher heat dissipation property, and it is possible to release the heat of the logic board 41A or the sensor board 20 more efficiently to the outside. It is to be noted that although FIG. 15D illustrates an example of a case where the concave portion 45U has the gap AG, the metal film 46 may fill the inside of the concave portion 45U. In addition, the metal film 46 may be provided so as to cover the convex portion 45T.

### Fifth Modification Example

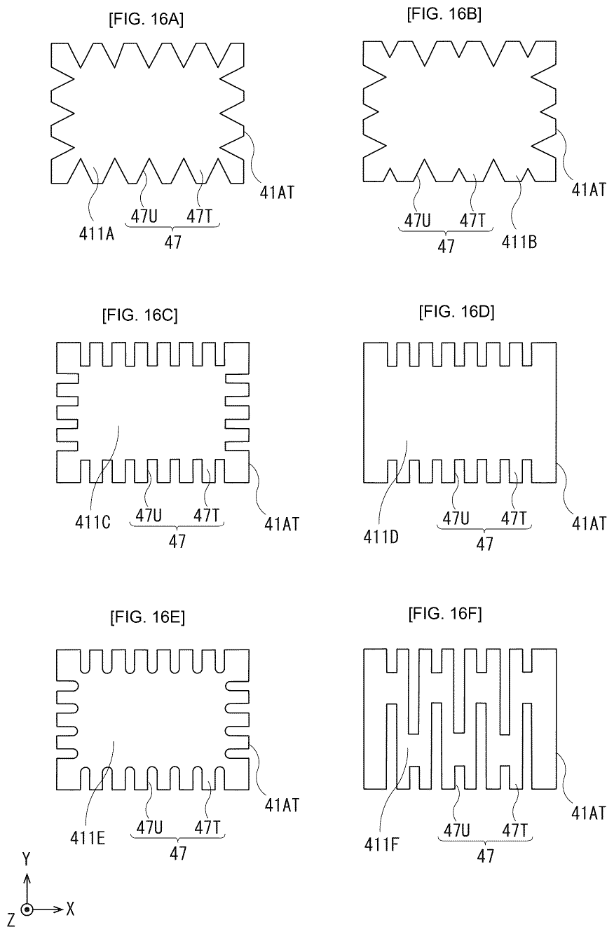

Parts (A) to (F) of FIG. 16 are each a planar schematic diagram illustrating a configuration example of corresponding one of the semiconductor substrates 411 (411A to 411F) of the logic board to be used for a solid-state imaging device of a fifth modification example (hereinafter referred to as Modification Example 3-5) of the present embodiment.

In the solid-state imaging device 3 according to the third embodiment, the front surface 41AFS of the semiconductor substrate 411 has the concave-convex structure 45. In contrast, in each of the semiconductor substrates 411 (411A to 41F) of Modification Example 3-5, the end surface 41AT has a concave-convex structure 47 as illustrated in parts (A) to (F) of FIG. 16. The concave-convex structure 47 includes a plurality of concave portions 47U and a plurality of convex portions 47T. The front surface 41AFS of each of the semiconductor substrates 411 (411A to 41F) may be a flat surface subjected to a planarization process such as CMP, or may have the concave-convex structure 45.

Specifically, in the semiconductor substrate 411A illustrated in part (A) of FIG. 16 and the semiconductor substrate 411B illustrated in part (B) of FIG. 16, the plurality of concave portions 47U having substantially triangular shape are formed on the end surface 41AT in plane view. It is to be noted that all of the concave portions 47U in the semiconductor substrate 411A have substantially the same size and shape as each other. In contrast, among the concave portions 47U in the semiconductor substrate 411B, the size of some of the concave portions 47U is different from the size of some of the other concave portions 47U.

Further, in the semiconductor substrate 411C illustrated in part (C) of FIG. 16, the semiconductor substrate 411C illustrated in part (D) of FIG. 16, and the semiconductor substrate 411F illustrated in part (F) of FIG. 16, the plurality of concave portions 47U having substantially rectangular shape are formed on the end surface 41AT in plane view. In addition, in the semiconductor substrate 411E illustrated in part (E) of FIG. 16, the plurality of concave portions 47U having substantially U shape are formed on the end surface 41AT in plane view. As described above, the numbers, shapes, sizes (lengths and widths), arrangement position, and the like of the plurality of concave portions 47U may be set as desired.

In the solid-state imaging device including the logic board 41A that includes any one of the semiconductor substrates 411 (411A to 411F) of Modification Example 3-5, the end surface 41AT has the concave-convex structure 47, which increases the surface area of the logic board 41A as compared with the logic board 41 of the solid-state imaging device 1 according to the first embodiment, for example. Thus, the logic board 41A has a high heat dissipation property, and it is possible to release the heat of the logic board 41A or the sensor board 20 efficiently to the outside.

### Sixth Modification Example

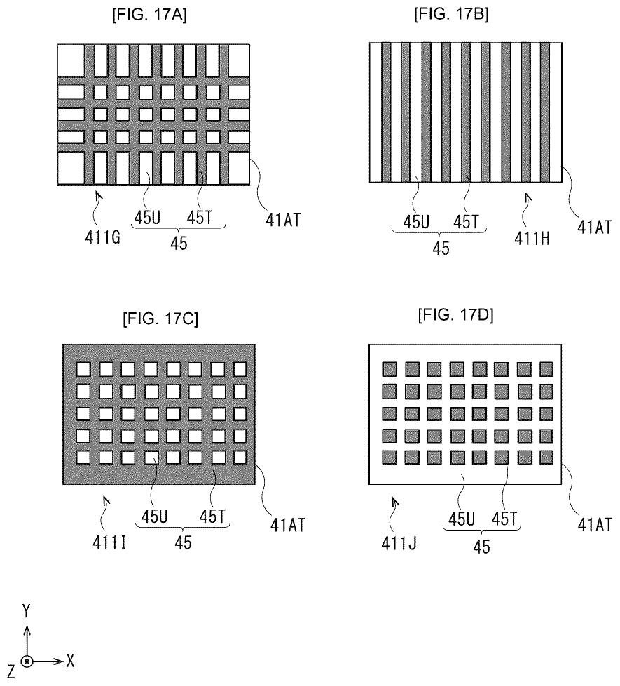

Parts (A) to (D) of FIG. 17 are each a planar schematic diagram illustrating a configuration example of corresponding one of the semiconductor substrates 411 (411G to 411J) of the logic board to be used for a solid-state imaging device of a sixth modification example (hereinafter referred to as Modification Example 3-6) of the present embodiment. As illustrated in each of parts (A) to (D) of FIG. 17, a layout of the concave portions 45U and the convex portions 45T of the concave-convex structure 45 may be selected as desired.

### Seventh Modification Example

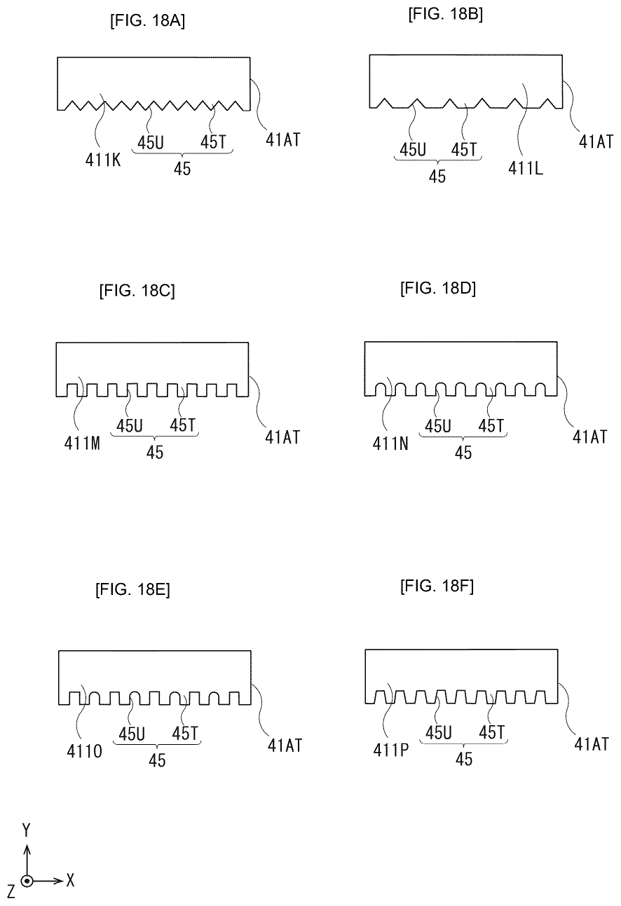

Parts (A) to (F) of FIG. 18 are each a planar schematic diagram illustrating a configuration example of corresponding one of the semiconductor substrates 411 (411K to 411P) of the logic board to be used for a solid-state imaging device of a seventh modification example (hereinafter referred to as Modification Example 3-7) of the present embodiment. As illustrated in each of parts (A) to (F) of FIG. 18, respective shapes and positions of the concave portions 45U and the convex portions 45T of the concave-convex structure 45 may be selected as desired.

### 7. Fourth Embodiment

### [Configuration of Solid-State Imaging Device 4]

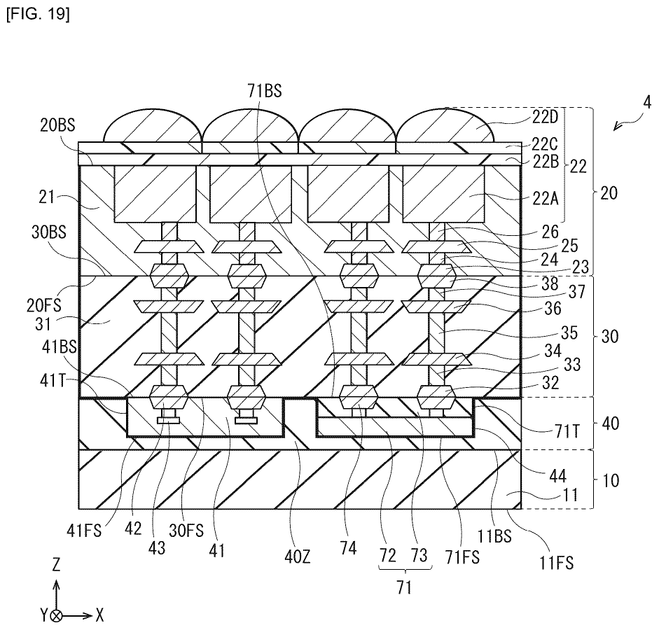

FIG. 19 schematically illustrates a configuration example of a solid-state imaging device 4 according to a fourth embodiment of the present disclosure. FIG. 19 illustrates a cross-sectional configuration example of the solid-state imaging device 4, and corresponds to FIG. 9A illustrating the solid-state imaging device 2 according to the second embodiment described above.

In the solid-state imaging device 2 according to the second embodiment described above, the hollow V is provided in the periphery of the logic board 41 and in the periphery of the heat dissipation board 71 in the logic layer 40. In contrast, in the solid-state imaging device 4 according to the present embodiment, no hollow V is provided and an insulating layer 40Z is filled in the periphery of the logic board 41 and in the periphery of the heat dissipation board 71 in the logic layer 40. Except for that, the configuration of the solid-state imaging device 4 is substantially the same as the configuration of the solid-state imaging device 2.

The heat dissipation board 71 is also provided in the solid-state imaging device 4 of the present embodiment, which makes it possible to release the heat of the logic board 41 or the sensor board 20 efficiently to the outside.

### 8. Fifth Embodiment

### [Configuration of Solid-State Imaging Device 5]

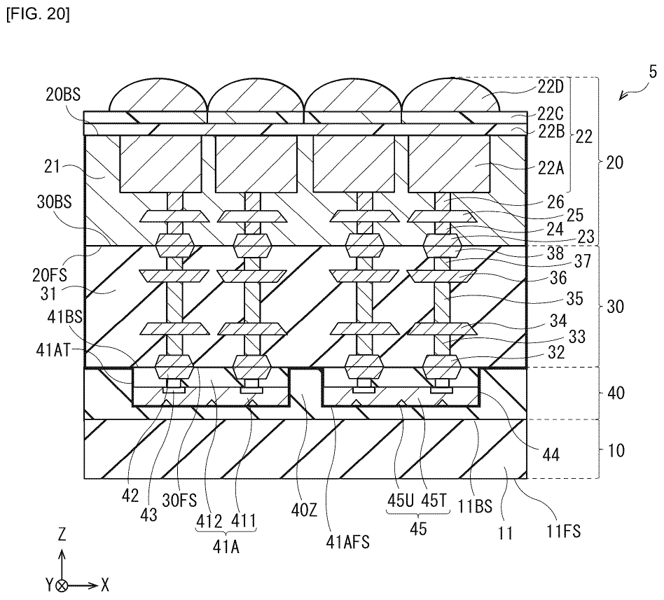

FIG. 20 schematically illustrates a configuration example of a solid-state imaging device 5 according to a fifth embodiment of the present disclosure. FIG. 20 illustrates a cross-sectional configuration example of the solid-state imaging device 5, and corresponds to FIG. 13A illustrating the solid-state imaging device 3 according to the third embodiment described above.

In the solid-state imaging device 3 according to the third embodiment described above, the hollow V is provided in the periphery of the logic board 41A in the logic layer 40. In contrast, in the solid-state imaging device 5 according to the present embodiment, no hollow V is provided and the insulating layer 40Z is filled in the periphery of the logic board 41A in the logic layer 40. Except for that, the configuration of the solid-state imaging device 5 is substantially the same as the configuration of the solid-state imaging device 3.

In the solid-state imaging device 5 of the present embodiment also, the logic board 41A has the concave-convex structure 45, which makes it possible to release the heat of the logic board 41A or the sensor board 20 efficiently to the outside.

### 9. Sixth Embodiment: Example of Application to Electronic Apparatus

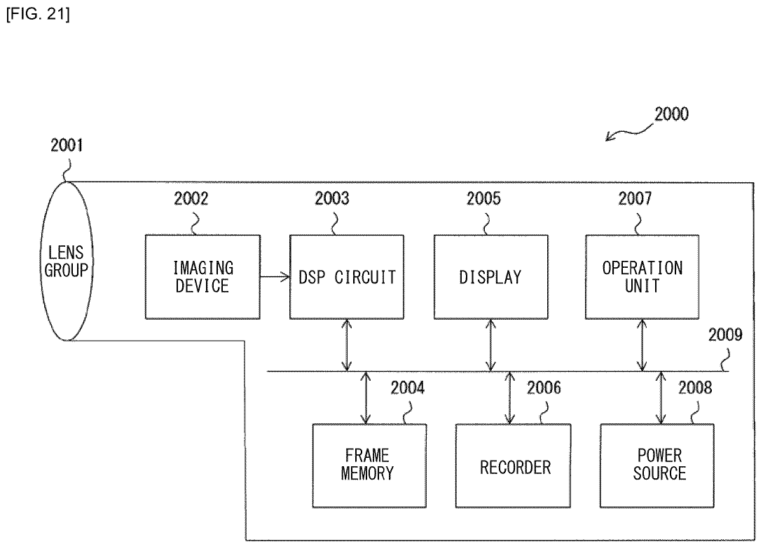

FIG. 21 is a block diagram illustrating a configuration example of a camera 2000 which is an electronic apparatus to which the present technology is applied.

The camera 2000 includes: an optical unit 2001 including a lens group, etc.; an imaging device 2002 to which the above-described solid-state imaging device 1, 1A, or the like (hereinafter referred to as the solid-state imaging device 1 or the like) is applied; and a DSP (Digital Signal Processor) circuit 2003 which is a camera signal processing circuit. Further, the camera 2000 also includes a frame memory 2004, a display 2005, a recorder 2006, an operation unit 2007, and a power source unit 2008. The DSP circuit 2003, the frame memory 2004, the display 2005, the recorder 2006, the operation unit 2007, and the power source unit 2008 are coupled to each other via a bus line 2009.

The optical unit 2001 takes in entering light (image light) from a subject and forms an image on an imaging plane of the imaging device 2002. The imaging device 2002 converts a light amount of the entering light, which is formed into the image on the imaging plane by the optical unit 2001, to an electric signal on a pixel-unit basis, and outputs the electric signal as a pixel signal.

The display 2005 includes, for example, a panel display device such as a liquid crystal panel or an organic EL panel. The display 2005 displays, for example, a moving image or a still image captured by the imaging device 2002. The recorder 2006 causes the moving image or the still image captured by the imaging device 2002 to be recorded in a recording medium such as a hard disk or a semiconductor memory.

The operation unit 2007 outputs an operation command regarding a variety of functions of the camera 2000 under operation by a user. The power source unit 2008 appropriately supplies a variety of power sources to serve as respective operation power sources for the DSP circuit 2003, the frame memory 2004, the display 2005, the recorder 2006, and the operation unit 2007, to these targets of supply.

As described above, the use of the above-described solid-state imaging device 1 or the like as the imaging device 2002 leads to an expectation of acquiring a favorable image.

### 10. Example of Practical Application to Mobile Body

The technology according to the present disclosure (present technology) is applicable to a variety of products. For example, the technology according to the present disclosure may be achieved as a device mounted on any type of mobile body such as a vehicle, an electric vehicle, a hybrid electric vehicle, a motorcycle, a bicycle, a personal mobility, an airplane, a drone, a vessel, a robot, and the like.

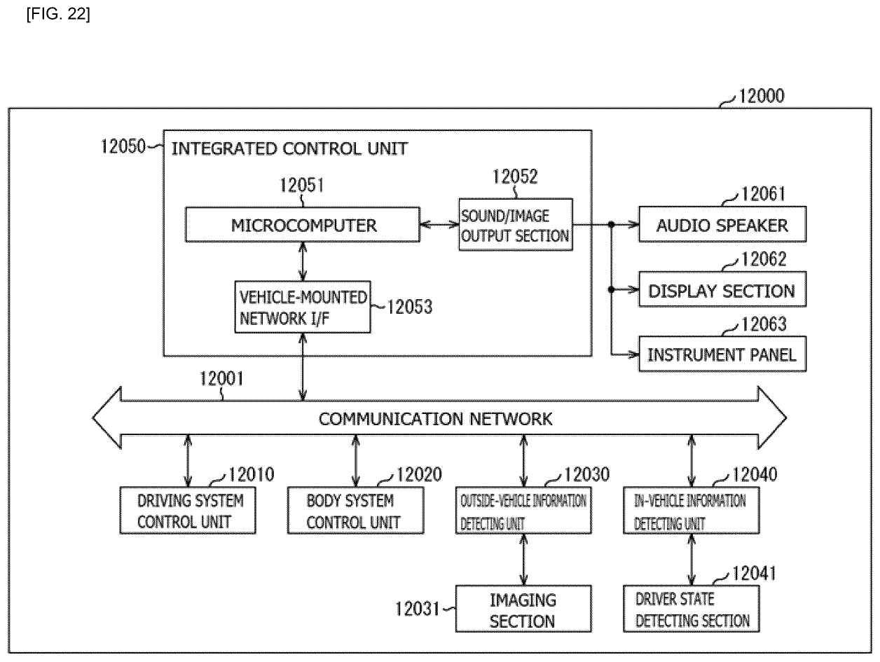

FIG. 22 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 22, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 22, an audio speaker 12061, a display section 12062, and an instrument panel 12063 are illustrated as the output device. The display section 12062 may, for example, include at least one of an on-board display and a head-up display.

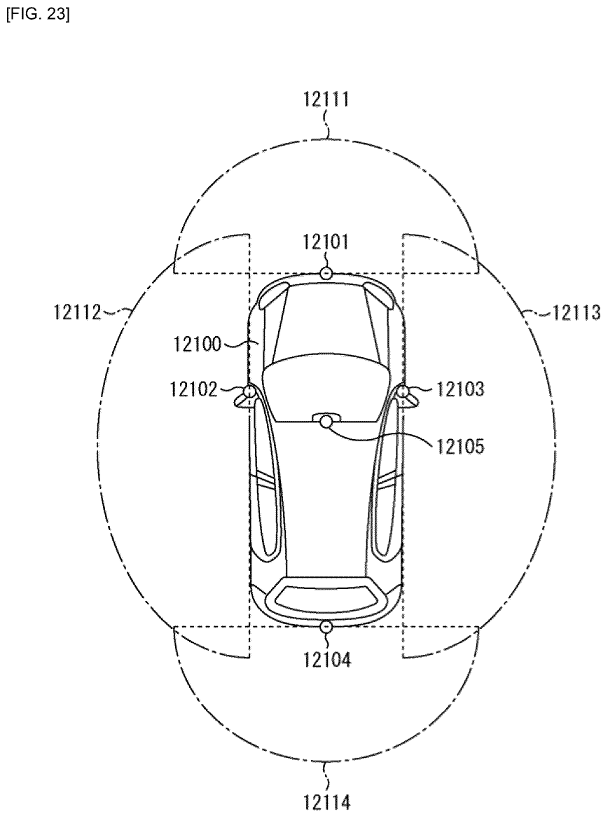

FIG. 23 is a diagram depicting an example of the installation position of the imaging section 12031.

In FIG. 23, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 23 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

In the forgoing, described is one example of the vehicle control system to which the technology according to the present disclosure is applicable. The technology according to the present disclosure is applicable to the imaging section 12031 among the above-described components. Specifically, the solid-state imaging device 1 illustrated in FIG. 1A, etc. or the like is applicable to the imaging section 12031. The application of the technology according to the present disclosure to the imaging section 12031 leads to an expectation of a superior operation of the vehicle control system.

### 11. Other Modification Examples

Although description has been given above of the present disclosure with reference to the embodiments and their modification examples, the present disclosure is not limited to the above-described embodiments, etc. and may be modified in a variety of ways. The locations, the dimensions, the shapes, etc. of the components described in the above-described embodiments, etc. may be set as desired.

Moreover, in the above-described embodiments, etc. the logic circuit and the memory circuit have been taken as examples of the signal processing circuit; however, the present disclosure is not limited thereto. The signal processing circuit according to the present disclosure includes, for example, one or more of a logic circuit, a memory circuit, a power circuit, an image signal compression circuit, a clock circuit, and an optical communication conversion circuit.

It is to be noted that effects described herein are merely examples, and the description thereof is non-limiting. Further, any other effect may be provided. Moreover, the present technology may have the following configurations.

(1)

An electronic device including:
a first device board;
a second device board that is stacked on the first device board and electrically coupled to the first device board, and has an area larger than an area of the first device board;
a hollow that surrounds, along a plane orthogonal to a stacking direction of the first device board and the second device board, at least a portion of a periphery of the first device board.
   (2)

The electronic device according to (1), in which
the electronic device includes a plurality of the first device boards spaced apart from each other along the plane, and
the hollow is provided in at least a portion of a space between the plurality of first device boards.
   (3)

The electronic device according to (1) and (2), in which the hollow communicates with an outside.

(4)

The electronic device according to any one of (1) to (3), in which at least a portion of the hollow is defined by a first metal film, the first metal film covering the first device board.

(5)

The electronic device according to (4), in which the first metal film continuously covers an end surface of the first device board and a front surface of the first device board, the front surface being on an opposite side of the second device board.

(6)

The electronic device according to (4), in which the first metal film includes at least one of Al (aluminum), W (tungsten), or Cu (copper).

(7)

The electronic device according to any one of (1) to (6), further including
a support board that is provided on an opposite side of the second device board as viewed from the first device board, and supports the first device board via a second metal film, in which
at least a portion of the hollow is defined by the first metal film covering the first device board, and the second metal film.
   (8)

The electronic device according to (7), in which the first metal film and the second metal film are integrated with each other and configure a metal frame.

(9)

The electronic device according to (7) or (8), in which the support board includes a concave portion that accommodates at least a portion of the first device board in a thickness direction.

(10)

The electronic device according to any one of (7) to (9), in which an inner surface of the concave portion is covered with the second metal film.

(11)

The electronic device according to (9) or (10), in which the hollow is also present between the first device board and the support board.

(12)

The electronic device according to any one of (9) to (11), in which a front-surface-covering portion of the first metal film and a bottom-surface-covering portion of the second metal film are in contact with each other, the front-surface-covering portion covering a front surface of the first device board, the bottom-surface-covering portion covering a bottom surface of the concave portion of the support board.

(13)

The electronic device according to any one of (1) to (12), further including
an additional board that is disposed adjacent to the first device board along the plane with the hollow interposed between the additional board and the first device board.
   (14)

The electronic device according to any one of (1) to (13), in which
the second device board is a sensor board provided with an imaging element, the imaging element including a plurality of pixels and is configured to generate a pixel signal by receiving external light for each of the pixels, and
the first device board is a circuit board including a signal processing circuit that performs a signal process on the pixel signal.
   (15)

The electronic device according to (13) or (14), in which the signal processing circuit includes at least one of a logic circuit, a memory circuit, a power circuit, an image signal compression circuit, a clock circuit, or an optical communication conversion circuit.

(16)

The electronic device according to (1), further including
a third device board, in which
the third device board is provided at a position adjacent to the first device board along the plane orthogonal to the stacking direction, and has an area smaller than the area of the second device board.
   (17)

The electronic device according to (16), in which the third device board has a heat conductivity higher than a heat conductivity of the first device board.

(18)

The electronic device according to (16) or (17), in which the third device board has a heat conductivity higher than a heat conductivity of the second device board.

(19)

The electronic device according to any one of (16) to (18), in which the third device board includes a metal layer that extends along the plane orthogonal to the stacking direction.

(20)

The electronic device according to any one of (16) to (19), in which the third device board includes a metal layer that extends along the plane orthogonal to the stacking direction, and one or more fins provided upright on the metal layer.

(21)

The electronic device according to any one of (16) to (19), in which the third device board includes a cooling element.

(22)

The electronic device according to (1), in which at least a portion of a surface, of the first device board, other than an opposed surface has a concave-convex structure, the opposed surface being opposed to the second device board.

(23)

The electronic device according to (22), in which the surface, of the first device board, having the concave-convex structure is a front surface on an opposite side of the opposed surface, an end surface coupling the opposed surface and the front surface, or both the front surface and the end surface.

(24)

The electronic device according to (22) or (23), in which the surface, of the first device board, having the concave-convex structure has an arithmetic mean roughness Ra value greater than 0.2 nm or has a root mean square roughness Rms value greater than 0.25 nm.

(25)

The electronic device according to any one of (22) to (24), in which
at least a portion of the hollow is defined by a first metal film covering the first device board, and
the first metal film continuously covers an end surface of the first device board and a front surface of the first device board, the front surface being on an opposite side of the second device board.
   (26)

The electronic device according to (25), further including
a second metal film that covers at least a portion of the front surface of the first device board.
   (27)

The electronic device according to (25), in which a gap is present between the front surface of the first device board and the first metal film.

(28)

The electronic device according to (22), in which two or more concave portions having different depths are formed on a front surface of the first device board, the front surface being on an opposite side to the opposed surface.

This application claims the benefit of Japanese Priority Patent Application JP2022-119066 filed with the Japan Patent Office on Jul. 26, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. An electronic device comprising:
a first device board;
a second device board that is stacked on the first device board and electrically coupled to the first device board, and has an area larger than an area of the first device board;
a hollow that surrounds, along a plane orthogonal to a stacking direction of the first device board and the second device board, at least a portion of a periphery of the first device board.

2. The electronic device according to claim 1, wherein
the electronic device includes a plurality of the first device boards spaced apart from each other along the plane, and
the hollow is provided in at least a portion of a space between the plurality of first device boards.

3. The electronic device according to claim 1, wherein the hollow communicates with an outside.

4. The electronic device according to claim 1, wherein at least a portion of the hollow is defined by a first metal film, the first metal film covering the first device board.

5. The electronic device according to claim 4, wherein the first metal film continuously covers an end surface of the first device board and a front surface of the first device board, the front surface being on an opposite side of the second device board.

6. The electronic device according to claim 4, wherein the first metal film includes at least one of Al (aluminum), W (tungsten), or Cu (copper).

7. The electronic device according to claim 1, further comprising
a support board that is provided on an opposite side of the second device board as viewed from the first device board, and supports the first device board via a second metal film, wherein
at least a portion of the hollow is defined by the first metal film covering the first device board, and the second metal film.

8. The electronic device according to claim 7, wherein the first metal film and the second metal film are integrated with each other and configure a metal frame.

9. The electronic device according to claim 7, wherein the support board includes a concave portion that accommodates at least a portion of the first device board in a thickness direction.

10. The electronic device according to claim 9, wherein an inner surface of the concave portion is covered with the second metal film.

11. The electronic device according to claim 9, wherein the hollow is also present between the first device board and the support board.

12. The electronic device according to claim 9, wherein a front-surface-covering portion of the first metal film and a bottom-surface-covering portion of the second metal film are in contact with each other, the front-surface-covering portion covering a front surface of the first device board, the bottom-surface-covering portion covering a bottom surface of the concave portion of the support board.

13. The electronic device according to claim 1, further comprising
an additional board that is disposed adjacent to the first device board along the plane with the hollow interposed between the additional board and the first device board.

14. The electronic device according to claim 1, wherein
the second device board is a sensor board provided with an imaging element, the imaging element including a plurality of pixels and is configured to generate a pixel signal by receiving external light for each of the pixels, and
the first device board is a circuit board including a signal processing circuit that performs a signal process on the pixel signal.

15. The electronic device according to claim 14, wherein the signal processing circuit includes at least one of a logic circuit, a memory circuit, a power circuit, an image signal compression circuit, a clock circuit, or an optical communication conversion circuit.

16. The electronic device according to claim 1, further comprising
a third device board, wherein
the third device board is provided at a position adjacent to the first device board along the plane orthogonal to the stacking direction, and has an area smaller than the area of the second device board.

17. The electronic device according to claim 16, wherein the third device board has a heat conductivity higher than a heat conductivity of the first device board.

18. The electronic device according to claim 16, wherein the third device board has a heat conductivity higher than a heat conductivity of the second device board.

19. The electronic device according to claim 16, wherein the third device board includes a metal layer that extends along the plane orthogonal to the stacking direction.

20. The electronic device according to claim 16, wherein the third device board includes a metal layer that extends along the plane orthogonal to the stacking direction, and one or more fins provided upright on the metal layer.

21. The electronic device according to claim 16, wherein the third device board includes a cooling element.

22. The electronic device according to claim 1, wherein at least a portion of a surface, of the first device board, other than an opposed surface has a concave-convex structure, the opposed surface being opposed to the second device board.

23. The electronic device according to claim 22, wherein the surface, of the first device board, having the concave-convex structure is a front surface on an opposite side of the opposed surface, an end surface coupling the opposed surface and the front surface, or both the front surface and the end surface.

24. The electronic device according to claim 22, wherein the surface, of the first device board, having the concave-convex structure has an arithmetic mean roughness Ra value greater than 0.2 nm or has a root mean square roughness Rms value greater than 0.25 nm.

25. The electronic device according to claim 22, wherein
at least a portion of the hollow is defined by a first metal film covering the first device board, and
the first metal film continuously covers an end surface of the first device board and a front surface of the first device board, the front surface being on an opposite side of the second device board.

26. The electronic device according to claim 25, further comprising
a second metal film that covers at least a portion of the front surface of the first device board.

27. The electronic device according to claim 25, wherein a gap is present between the front surface of the first device board and the first metal film.

28. The electronic device according to claim 22, wherein two or more concave portions having different depths are formed on a front surface of the first device board, the front surface being on an opposite side to the opposed surface.
